(19) United States
(12) Patent Application Publication
(10) Pub. No.: US 2024/0421059 A1
(43) Pub. Date: Dec. 19, 2024

(54) WIRING SUBSTRATE AND MANUFACTURING METHOD OF WIRING SUBSTRATE

(71) Applicant: TOPPAN Holdings Inc, Tokyo (JP)

(72) Inventor: Tsukasa Nakamura, Tokyo (JP)

(73) Assignee: TOPPAN Holdings Inc., Tokyo (JP)

(21) Appl. No.: 18/741,388

(22) Filed: Jun. 12, 2024

(30) Foreign Application Priority Data
Jun. 14, 2023 (JP) 2023-098046

(51) Int. Cl. H01L 23/498; H01L 21/48; H01L 23/15

(52) U.S. Cl. CPC H01L 23/49822; H01L 21/4857; H01L 23/15; H01L 28/40

(57) ABSTRACT

A wiring substrate includes: a glass substrate including a first face; a capacitor including a first electrode provided above the first face of the glass substrate, a dielectric layer provided above the first electrode, and a second electrode provided above the dielectric layer; and a first insulating layer covering the first face of the glass substrate and the capacitor. A third face of the first electrode that faces a second face of the dielectric layer includes a contact portion that is in contact with the second face of the dielectric layer, and a non-contact portion that is not in contact with the second face of the dielectric layer. An outer circumference of the contact portion has a sawtooth shape.

### CROSS-REFERENCE TO RELATED APPLICATIONS

This application is based upon and claims the benefit of priority from Japanese Patent Application No. 2023-098046, filed Jun. 14, 2023, the entire contents of which are incorporated herein by reference.

### FIELD

The present invention relates to a wiring substrate and a manufacturing method of the wiring substrate.

### BACKGROUND

A multilayer wiring substrate that uses a glass material as a core substrate is known. The multilayer wiring substrate is used as a glass interposer in many cases. A capacitor including an MIM (Metal Insulator Metal) structure in which a dielectric layer is sandwiched between metal layers may be formed on the multilayer wiring substrate as part of a passive circuit.

For example, a capacitor of the MIM structure is formed as follows. First, a first seed layer is provided above a glass substrate, a first conductive layer is provided, for example, by plating, using the first seed layer. The first seed layer and the first conductive layer are used as a bottom electrode (metal layer) of the capacitor. Then, a dielectric layer is provided above the bottom electrode. Next, a second seed layer is provided above the dielectric layer, and a second conductive layer is provided, for example, by plating, using the second seed layer. The second seed layer and the second conductive layer are used as a top electrode (metal layer) of the capacitor. After the capacitor of the MIM structure is formed, a first insulating layer (e.g., resin) is formed to cover the capacitor.

Patent Literature 1 describes a structure in which a step is formed near the boundary between the bottom electrode and the dielectric layer of the capacitor of the MIM structure.

### CITATION LIST

### Patent Literature

Patent Literature 1: International Publication No. 2019/244382

### SUMMARY

In a capacitor of the MIM structure in which a bottom electrode and a top electrode are formed using seed layers, the seed layers are thin, so that side etching of the bottom electrode (conductive layer) is likely to occur during removal of the seed layers, for example.

In a case where a side-etched portion of the bottom electrode is under the dielectric layer, the capacitor of the MIM structure may not be reliably covered with resin (insulating layer) because the resin may not reach the contact area between the dielectric layer and the bottom electrode in the side-etched portion. In this case, the adhesion between the dielectric layer and the bottom electrode, and the resin is weak, and peeling may occur between the dielectric layer and the bottom electrode, and the resin. That is, peeling may occur between the capacitor and the insulating layer.

An object of the present invention is to provide a technique that can sufficiently ensure adhesion between a capacitor and an insulating layer and suppress the occurrence of peeling between the capacitor and the insulating layer.

According to one aspect of the present invention, there is provided a wiring substrate comprising: a glass substrate including a first face; a capacitor including a first electrode provided above the first face of the glass substrate, a dielectric layer provided above the first electrode, and a second electrode provided above the dielectric layer; and a first insulating layer covering the first face of the glass substrate and the capacitor, wherein a third face of the first electrode that faces a second face of the dielectric layer includes a contact portion that is in contact with the second face of the dielectric layer, and a non-contact portion that is not in contact with the second face of the dielectric layer, and an outer circumference of the contact portion has a sawtooth shape.

According to another aspect of the present invention, there is provided the wiring substrate in the above aspect, wherein an LER (Line Edge Roughness) of the contact portion is not less than 1000 nm and not more than 5000 nm.

According to still another aspect of the present invention, there is provided the wiring substrate in any one of the above aspects, wherein an outer circumference of the second face of the dielectric layer has a rectangular shape.

According to still another aspect of the present invention, there is provided the wiring substrate in any one of the above aspects, wherein the first electrode includes a structure in which a first seed layer and a first conductive layer are stacked, and the outer circumference of the contact portion is located inward of an end face of the dielectric layer in a range of not less than 1.2 times of a thickness of the first seed layer and not more than 40 times thereof.

According to still another aspect of the present invention, there is provided the wiring substrate in any one of the above aspects, wherein the second electrode includes a structure in which a second seed layer and a second conductive layer are stacked, and the outer circumference of the contact portion is located inward of an end face of the dielectric layer in a range of not less than 1.2 times of a thickness of the second seed layer and not more than 40 times thereof.

According to still another aspect of the present invention, there is provided the wiring substrate in any one of the above aspects, wherein a distance between the outer circumference of the contact portion and an end face of the dielectric layer is greater than 0 μm and not more than 12 μm.

According to still another aspect of the present invention, there is provided the wiring substrate in any one of the above aspects, wherein the first electrode is thicker at the contact portion than at the non-contact portion.

According to still another aspect of the present invention, there is provided the wiring substrate in any one of the above aspects, wherein the dielectric layer is made of a transparent material.

According to still another aspect of the present invention, there is provided the wiring substrate in any one of the above aspects, wherein the dielectric layer is made of silicon nitride and has a thickness of not less than 10 nm and not more than 5000 nm.

According to still another aspect of the present invention, there is provided the wiring substrate in any one of the above aspects, wherein the third face of the first electrode is greater in size than the second face of the dielectric layer.

According to still another aspect of the present invention, there is provided the wiring substrate in any one of the above aspects, wherein a fourth face of the dielectric layer facing the second face is greater in size than a fifth face of the second electrode facing the fourth face of the dielectric layer.

According to still another aspect of the present invention, there is provided the wiring substrate in any one of the above aspects, wherein the first insulating layer is made of an insulating resin.

According to still another aspect of the present invention, there is provided the wiring substrate in any one of the above aspects, further comprising an adhesion layer provided between the first electrode and the dielectric layer.

According to still another aspect of the present invention, there is provided a manufacturing method of a wiring substrate, comprising: forming a first seed layer above a glass substrate; forming a first conductive layer on part of the first seed layer; forming a dielectric layer above the first seed layer and the first conductive layer; forming a second seed layer above the dielectric layer; forming a second conductive layer on part of the second seed layer; forming a mask covering the second conductive layer and removing the second seed layer and the dielectric layer; etching an end portion of a surface of the first conductive layer; removing the first seed layer; and forming a first insulating layer to cover a surface of the glass substrate, the first seed layer, the first conductive layer, the dielectric layer, the second seed layer, and the second conductive layer.

According to still another aspect of the present invention, there is provided the manufacturing method of the wiring substrate in the above aspect, wherein etching the end portion of the surface of the first conductive layer includes generating roughness whose surface roughness is in a range of not less than 30 nm and not more than 70 nm at the end portion of the surface of the first conductive layer.

According to still another aspect of the present invention, there is provided the manufacturing method of the wiring substrate in any one of the above aspects, wherein removing the first seed layer includes etching the first seed layer in a range of not less than 1.2 times of a thickness of the first seed layer and not more than 40 times thereof.

According to still another aspect of the present invention, there is provided the manufacturing method of the wiring substrate in the above aspect, wherein forming the first insulating layer includes embedding the first insulating layer in a portion where part of the first conductive layer is removed as a result of removal of the first seed layer.

According to still another aspect of the present invention, there is provided a manufacturing method of a wiring substrate, comprising: forming a first seed layer above a glass substrate; forming a first conductive layer on part of the first seed layer; removing the first seed layer; forming a dielectric layer above the glass substrate and the first conductive layer; forming a mask covering part of the dielectric layer and removing the dielectric layer; etching an end portion of a surface of the first conductive layer; forming a second seed layer above the glass substrate, the first conductive layer, and the dielectric layer; forming a second conductive layer on part of the second seed layer; forming a mask covering the second conductive layer and removing the second seed layer; and forming a first insulating layer to cover a surface of the glass substrate, the first seed layer, the first conductive layer, the dielectric layer, the second seed layer, and the second conductive layer.

According to still another aspect of the present invention, there is provided the manufacturing method of the wiring substrate in the above aspect, wherein etching the end portion of the surface of the first conductive layer includes generating roughness whose surface roughness is in a range of not less than 30 nm and not more than 70 nm at the end portion of the surface of the first conductive layer.

According to still another aspect of the present invention, there is provided the manufacturing method of the wiring substrate in any one of the above aspects, wherein removing the second seed layer includes etching the second seed layer in a range of not less than 1.2 times of a thickness of the second seed layer and not more than 40 times thereof.

According to still another aspect of the present invention, there is provided the manufacturing method of the wiring substrate in the above aspect, wherein forming the first insulating layer includes embedding the first insulating layer in a portion where part of the first conductive layer is removed as a result of removal of the second seed layer.

According to the present invention, a technique is provided that can sufficiently ensure adhesion between a capacitor and an insulating layer and can suppress the occurrence of peeling between the capacitor and the insulating layer.

### BRIEF DESCRIPTION OF THE DRAWINGS

FIG. 1 is a cross-sectional view of a wiring substrate according to a first embodiment of the present invention.

FIG. 2 is a cross-sectional view in which part of the wiring substrate depicted in FIG. 1 is shown in an enlarged scale.

FIG. 3 is a top view of the wiring substrate depicted in FIG. 1.

FIG. 4 is a top view in which part of the wiring substrate depicted in FIG. 3 is shown in an enlarged scale.

FIG. 5 is a cross-sectional view illustrating one step performed in a method for manufacturing the wiring substrate depicted in FIG. 1.

FIG. 6 is a cross-sectional view illustrating another step performed in the method for manufacturing the wiring substrate depicted in FIG. 1.

FIG. 7 is a cross-sectional view illustrating still another step performed in the method for manufacturing the wiring substrate depicted in FIG. 1.

FIG. 8 is a cross-sectional view illustrating still another step performed in the method for manufacturing the wiring substrate depicted in FIG. 1.

FIG. 9 is a cross-sectional view illustrating still another step performed in the method for manufacturing the wiring substrate depicted in FIG. 1.

FIG. 10 is a cross-sectional view illustrating still another step performed in the method for manufacturing the wiring substrate depicted in FIG. 1.

FIG. 11 is a cross-sectional view illustrating still another step performed in the method for manufacturing the wiring substrate depicted in FIG. 1.

FIG. 12 is a cross-sectional view in which part of the cross-sectional view depicted in FIG. 11 is shown in an enlarged scale.

FIG. 13 is a cross-sectional view illustrating still another step performed in the method for manufacturing the wiring substrate depicted in FIG. 1.

FIG. 14 is a cross-sectional view illustrating one step performed in the method for manufacturing a wiring substrate according to a second embodiment of the present invention.

FIG. 15 is a cross-sectional view illustrating another step performed in the method for manufacturing the wiring substrate according to the second embodiment of the present invention.

FIG. 16 is a cross-sectional view illustrating still another step performed in the method for manufacturing the wiring substrate according to the second embodiment of the present invention.

FIG. 17 is a cross-sectional view illustrating still another step performed in the method for manufacturing the wiring substrate according to the second embodiment of the present invention.

FIG. 18 is a cross-sectional view in which part of the cross-sectional view depicted in FIG. 17 is shown in an enlarged scale.

FIG. 19 is a cross-sectional view illustrating still another step performed in the method for manufacturing the wiring substrate according to the second embodiment of the present invention.

FIG. 20 is a cross-sectional view illustrating still another step performed in the method for manufacturing the wiring substrate according to the second embodiment of the present invention.

### DETAILED DESCRIPTION

Embodiments of the present invention will now be described with reference to the accompanying drawings. The embodiments described below are more specific implementations of the aspects described above. The matters described below can be incorporated into each of the above aspects alone or in combination.

In addition, the embodiments shown below illustrate examples of configurations for embodying the technical idea of the present invention, and the technical idea of the present invention is not limited by the materials, shapes, structures, etc. of the constituent members described below. Various modifications can be made to the technical idea of the present invention within the technical scope defined by the claims.

Elements having the same or similar functions will be designated by the same reference numerals in the drawings referred to below, and a redundant description of such elements will be omitted. In addition, the drawings are schematic, and the relationship between dimensions in one direction and dimensions in another direction, and the relationship between the dimensions of a certain member and the dimensions of other members may differ from the actual ones.

### <1> First Embodiment

### <1.1> Wiring Substrate

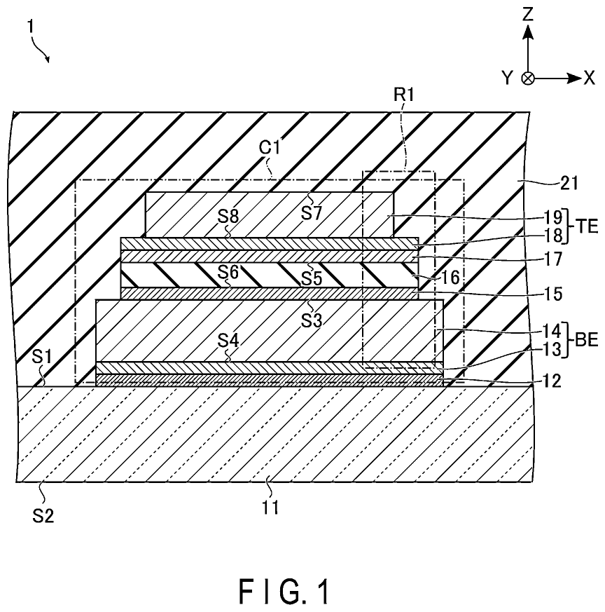

FIG. 1 is a cross-sectional view of a wiring substrate according to a first embodiment of the present invention.

The wiring substrate 1 shown in FIG. 1 is a glass core wiring substrate. According to one example, the wiring substrate 1 is a wiring substrate used as an interposer. That is, the wiring substrate 1 is a glass interposer.

As shown in FIG. 1, the wiring substrate 1 includes a glass substrate 11, a first adhesion layer 12, a first seed layer 13, a first conductive layer 14, a second adhesion layer 15, a dielectric layer 16, a third adhesion layer 17, a second seed layer 18, a second conductive layer 19, and a first insulating layer 21.

The glass substrate 11 is a transparent glass material having light transmittance. The components of the glass substrate 11 and the mixing ratio of the components are not particularly limited. An example of the glass substrate 11 is a glass material including silicate as a main component, but other glass materials may be used. Specific examples of the glass substrate 11 include non-alkali glass, alkali glass, borosilicate glass, quartz glass, sapphire glass, photosensitive glass, etc., but in a case where a semiconductor chip is mounted on the glass substrate 11, the non-alkali glass is more preferred.

It is preferable that the linear expansion coefficient of the glass substrate 11 is, for example, not less than −1 ppm/K and not more than 15.0 ppm/K. In a case where the linear expansion coefficient of the glass substrate 11 is less than −1 ppm/K, the glass material cannot be easily selected per se and cannot be manufactured at low cost. In a case where the linear expansion coefficient of the glass substrate 11 exceeds 15.0 ppm/K, the linear expansion coefficient of the glass substrate 11 differ greatly from those of other layers, and the connection reliability to other layers deteriorates. Furthermore, in a case where the semiconductor chip is mounted on the glass substrate 11, the connection reliability to the semiconductor chip deteriorates. It should be noted that the linear expansion coefficient of the glass substrate 11 is preferably not less than 0.5 ppm/K and not more than 8.0 ppm/K, and more preferably not less than 1.0 ppm/K and not more than 4.0 ppm/K. The method for manufacturing the glass substrate 11 is not particularly limited. Examples of the method for manufacturing the glass substrate 11 include a float method, a down-draw method, a fusion method, an up-draw method, a roll-out method, etc., but other methods may be used. That is, a glass material made by any method may be used as the glass substrate 11.

It is preferable that thickness of the glass substrate 11 is, for example, greater than 0 mm and not more than 1 mm. Considering the ease of the process of forming through holes in the glass substrate 11 and the ease of handling during manufacturing, it is more preferable that the thickness is not less than 0.1 mm and not more than 0.8 mm.

A functional film such as an antireflection film or an infrared (IR) cut filter may be formed on the glass substrate 11 in advance. Further, functions, such as strength imparting, antistatic imparting, coloring, texture control, may be imparted. Examples of these functional films include a hard coat film for imparting strength, an antistatic film for imparting antistatic property, an optical filter film for coloring, and an anti-glare, light scattering film, etc. for imparting texture control, but are not limited to these. As a method for forming these functional films, film forming techniques, such as vapor deposition, a sputtering method and a wet method, are used.

The glass substrate 11 includes a first face S1, and a second face S2 facing the first face S1. The first face S1 and the second face S2 are parallel to each other.

In the description below, a plane parallel to both the first face S1 and the second face S2 is defined as an XY plane. Directions perpendicular to each other in the XY plane are defined as an X direction and a Y direction. The direction substantially perpendicular to the XY plane is defined as a Z direction. The first face S1 is also referred to as the surface of the glass substrate 11. The second face S2 is also referred to as the back surface of the glass substrate 11.

Although not shown in FIG. 1, the glass substrate 11 is provided with one or more through holes each extending from the first face S1 to the second face S2. That is, each of the through holes penetrates the glass substrate 11 in the Z direction.

Each of the through holes has, for example, a tapered shape. That is, the opening diameter or cross-sectional area (an area of a cross section parallel to the first face S1) of the through hole increases from the first face S1 side toward the second face S2 side.

Each of the through holes may have, for example, an inverse tapered shape. That is, the opening diameter or cross-sectional area of each through hole may decrease from the first face S1 side toward the second face S2 side.

Each of the through holes may have a position (hereinafter referred to as a “first position”) where the opening diameter or cross-sectional area of the through hole takes a minimum value between the first face S1 and the second face S2. That is, the opening diameter or cross-sectional area of the through hole may decrease from the first face S1 side toward the first position, and may increase from the first position toward the second face S2 side. In other words, each of the through holes may have a shape having an inverse tapered portion from the first face S1 to the first position and a tapered portion from the first position to the second face S2.

Each of the through holes may have a position (hereinafter referred to as a “second position”) where the opening diameter or cross-sectional area of the through hole takes a maximum value between the first face S1 and the second face S2. That is, the opening diameter or cross-sectional area of the through hole may increase from the first face S1 side toward the second position, and may decrease from the second position toward the second face S2 side. In other words, each of the through holes may have a shape having a tapered portion from the first face S1 to the second position and an inverse tapered portion from the second position to the second face S2.

The first adhesion layer 12 is provided on the first face S1 of the glass substrate 11. The first adhesion layer 12 serves to increase the adhesion between the glass substrate 11 and the first seed layer 13. The material of the first adhesion layer 12 is, for example, Cu, Ni, Al, Ti, Cr, Mo, W, Ta, Au, Ir, Ru, Pd, Pt, AlSi, AlSiCu, AlCu, NiFe, Cu alloy alone, or a combination of these materials. Considering reliable adhesion, electrical conductivity, ease of manufacture, and manufacturing cost, the use of Ti is preferred.

The first adhesion layer 12 is formed, for example, by sputtering. It should be noted that in a case where the adhesion between the glass substrate 11 and the first seed layer 13 is sufficient, the first adhesion layer 12 need not be provided.

The thickness of the first adhesion layer 12 is preferably, for example, not less than 10 nm and not more than 1000 nm. In a case where the thickness of the first adhesion layer 12 is less than 10 nm, the adhesion may be insufficient. In a case where the thickness of the first adhesion layer 12 exceeds 1000 nm, it takes too much time to form the layer, resulting in a poor mass productivity, and it may take time to remove unnecessary portions. It should be noted that the thickness of the first adhesion layer 12 is more preferably not less than 10 nm and not more than 500 nm.

The first seed layer 13 is provided on the first adhesion layer 12 (above the first face S1 of the glass substrate 11). In a case where the first adhesion layer 12 is not provided, the first seed layer 13 is provided on the first face S1 of the glass substrate 11. The first seed layer 13 functions as a power supply layer for electrolytic plating used where the first conductive layer 14 is formed by a semi-additive method. The material of the first seed layer 13 is, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, Cu₃N₄, Cu alloy alone, or a combination of these materials.

The first seed layer 13 is formed, for example, by a sputtering method or a CVD (chemical vapor deposition) method. It should be noted that an electroless plating layer (electroless copper plating, electroless nickel plating, etc.) may be formed on the first seed layer 13.

The thickness of the first seed layer 13 is preferably, for example, not less than 50 nm and not more than 5000 nm. In a case where the thickness of the first seed layer 13 is less than 50 nm, a conduction failure may occur in the electrolytic plating process of the first conductive layer 14. In a case where the thickness of the first seed layer 13 exceeds 5000 nm, it may take time to remove unnecessary portions. It should be noted that the thickness of the first seed layer 13 is more preferably not less than 100 nm and not more than 500 nm. The thickness of the first seed layer 13 is the thickness of that portion of the first seed layer 13 which is provided on the first adhesion layer 12 (or on the glass substrate 11 in a case where the first adhesion layer 12 is not provided).

The first conductive layer 14 is provided on the first seed layer 13. As the material of the first conductive layer 14, copper is used, for example.

As a method for forming the first conductive layer 14, for example, electrolytic copper plating is preferable because it is simple, inexpensive and provides good electrical conductivity. In addition to the electrolytic copper plating, the first conductive layer 14 may be formed by electrolytic nickel plating, electrolytic chromium plating, electrolytic palladium plating, electrolytic gold plating, electrolytic rhodium plating, electrolytic iridium plating, or the like.

The thickness of the first conductive layer 14 (the thickness of the electrolytic copper plating) is preferably, for example, not less than 3 μm and not more than 30 μm. In a case where the thickness of the first conductive layer 14 is less than 3 μm, there is a possibility that the circuit will be lost due to the etching treatment performed after the formation of the first conductive layer 14. Furthermore, the connection reliability and electrical conductivity of the circuit may deteriorate. In a case where the thickness of the first conductive layer 14 exceeds 30 μm, a resist layer with a thickness exceeding 30 μm has to be formed, which increases the manufacturing cost. Furthermore, since the resist resolution deteriorates, fine wiring with a pitch of not more than 30 μm cannot be easily formed. It should be noted that the thickness of the first conductive layer 14 is more preferably not less than 5 μm and not more than 25 μm, and even more preferably not less than 10 μm and not more than 20 μm.

The first conductive layer 14 has a third face S3, and a fourth face S4 facing the third face S3. The fourth face S4 faces the first face S1 of the glass substrate 11. In the description below, the third face S3 is also referred to as the surface of the first conductive layer 14.

The second adhesion layer 15 is provided on the first conductive layer 14. The second adhesion layer 15 serves to increase the adhesion between the first conductive layer 14 and the dielectric layer 16. For the second adhesion layer 15, the materials exemplified for the first adhesion layer 12 can be used.

The second adhesion layer 15 is formed, for example, by a sputtering method. It should be noted that in a case where the adhesion between the first conductive layer 14 and the dielectric layer 16 is sufficient, the second adhesion layer 15 need not be provided.

Like the first adhesion layer 12, the thickness of the second adhesion layer 15 is preferably, for example, not less than 10 nm and not more than 1000 nm, and more preferably not less than 10 nm and not more than 500 nm.

The dielectric layer 16 is provided on the second adhesion layer 15 (above the first conductive layer 14). In a case where the second adhesion layer 15 is not provided, the dielectric layer 16 is provided on the first conductive layer 14. The material of the dielectric layer 16 is at least one material that is selected from a group including, for example, alumina, silica, silicon nitride, tantalum oxide, titanium oxide, calcium titanate, barium titanate, and strontium titanate, from the viewpoint of providing desired insulation property and relative dielectric constant.

The dielectric layer 16 is formed, for example, by a CVD method.

The thickness of the dielectric layer 16 is preferably, for example, not less than 10 nm and not more than 5000 nm. In a case where the thickness of the dielectric layer 16 is less than 10 nm, reliable insulation cannot be provided and a capacitor function cannot be obtained. In a case where the thickness of the dielectric layer 16 exceeds 5000 nm, it takes too much time to form the layer, resulting in a poor mass productivity, and it may take time to remove unnecessary portions. It should be noted that the thickness of the dielectric layer 16 is more preferably not less than 50 nm and not more than 1000 nm.

The dielectric layer 16 has a fifth face S5, and a sixth face S6 facing the fifth face S5. The sixth face S6 faces the third face S3 of the first conductive layer 14.

The third adhesion layer 17 is provided on the dielectric layer 16. The third adhesion layer 17 serves to increase the adhesion between the dielectric layer 16 and the second seed layer 18. For the third adhesion layer 17, the materials exemplified for the first adhesion layer 12 can be used.

The third adhesion layer 17 is formed, for example, by a sputtering method. In a case where the adhesion between the dielectric layer 16 and the second seed layer 18 is sufficient, the third adhesion layer 17 need not be provided.

Like the first adhesion layer 12, the thickness of the third adhesion layer 17 is preferably, for example, not less than 10 nm and not more than 1000 nm, and more preferably not less than 10 nm and not more than 500 nm. Although the first adhesion layer 12, the second adhesion layer 15 and the third adhesion layer 17 may differ in thickness, they preferably have the same thickness in order to simplify the structure.

The second seed layer 18 is provided on the third adhesion layer 17 (above the dielectric layer 16). In a case where the third adhesion layer 17 is not provided, the second seed layer 18 is provided on the dielectric layer 16. The second seed layer 18 functions as a power supply layer for electrolytic plating used where the second conductive layer 19 is formed by a semi-additive method. For the second seed layer 18, the materials exemplified for the first seed layer 13 can be used. The use of copper is preferable because unnecessary portions can be easily removed by etching.

The second seed layer 18 is formed, for example, by a sputtering method or a CVD method. It should be noted that an electroless plating layer (electroless copper plating, electroless nickel plating, or the like) may be formed on the second seed layer 18.

Like the first seed layer 13, the thickness of the second seed layer 18 is preferably, for example, not less than 50 nm and not more than 5000 nm, and more preferably not less than 100 nm and not more than 500 nm. The thickness of the second seed layer 18 is the thickness of that portion of the second seed layer 18 which is provided on the third adhesion layer 17 (or on the dielectric layer 16 in a case where the third adhesion layer 17 is not provided).

The second conductive layer 19 is provided on the second seed layer 18. As the material of the second conductive layer 19, for example, copper is used.

As a method for forming the second conductive layer 19, for example, electrolytic copper plating is preferable because it is simple, inexpensive and provides good electrical conductivity. In addition to the electrolytic copper plating, the second conductive layer 19 may be formed by electrolytic nickel plating, electrolytic chromium plating, electrolytic palladium plating, electrolytic gold plating, electrolytic rhodium plating, electrolytic iridium plating, or the like.

Like the first conductive layer 14, the thickness of the second conductive layer 19 (the thickness of electrolytic copper plating) is preferably, for example, not less than 3 μm and not more than 30 μm, more preferably not less than 5 μm and not more than 25 μm, and still more preferably not less than 10 μm and not more than 20 μm.

The second conductive layer 19 has a seventh face S7, and an eighth face S8 facing the seventh face S7. The eighth face S8 faces the fifth face S5 of the dielectric layer 16.

The first seed layer 13, first conductive layer 14, dielectric layer 16, second seed layer 18, and second conductive layer 19 described above jointly constitute a capacitor C1 of an MIM structure (hereinafter referred to as “MIM capacitor”). In other words, the wiring substrate 1 includes the MIM capacitor C1. The first seed layer 13 and the first conductive layer 14 serve as the bottom electrode BE of the MIM capacitor C1. The bottom electrode BE includes a structure in which the first seed layer 13 and the first conductive layer 14 are stacked, and is provided above the first face S1 of the glass substrate 11. In this specification, both the structure constituted by the first conductive layer 14 alone and the structure in which the first adhesion layer 12, the first seed layer 13, and the first conductive layer 14 are stacked will be referred to as the bottom electrode BE. The dielectric layer 16 is a dielectric layer of the MIM capacitor C1. The dielectric layer 16 is provided above the bottom electrode BE. The second seed layer 18 and the second conductive layer 19 serve as the top electrode TE of the MIM capacitor C1. The top electrode TE includes a structure in which the second seed layer 18 and the second conductive layer 19 are stacked, and is provided above the dielectric layer 16. In this specification, both the structure constituted by the second conductive layer 19 alone and the structure in which the third adhesion layer 17, the second seed layer 18, and the second conductive layer 19 are stacked will be referred to as the top electrode TE.

In the example shown in FIG. 1, the size of the third face S3 of the first conductive layer 14 is larger than the size of the sixth face S6 of the dielectric layer 16. The size of the fifth face S5 of the dielectric layer 16 is larger than the size of the eighth face S8 of the second conductive layer 19. With the sizes of the first conductive layer 14, dielectric layer 16 and second conductive layer 19 being formed as above, the occurrence of short circuit can be suppressed between the bottom electrode BE and the top electrode TE, and the process can be simplified.

The first insulating layer 21 covers the first face S1 of the glass substrate 11, the first adhesion layer 12, the first seed layer 13, the first conductive layer 14, the second adhesion layer 15, the dielectric layer 16, the third adhesion layer 17, the second seed layer 18, and the second conductive layer 19. That is, the first insulating layer 21 covers the first face S1 of the glass substrate 11 and the capacitor C1. It should be noted that vias may be provided in the first insulating layer 21 at the positions of the first conductive layer 14 and the second conductive layer 19.

The material of the first insulating layer 21 is preferably an insulating resin, for example. The components of the insulating resin, the mixing ratio of the components, and the method for manufacturing the insulating resin are not particularly limited. Examples of the insulating resin include epoxy resin, polyimide, maleimide resin, polyethylene terephthalate, polyphenylene oxide, liquid crystal polymer, a composite material of these, photosensitive polyimide resin, photosensitive polybenzoxazole, photosensitive acrylic-epoxy resin, etc.

For example, it is preferable that the thickness of the first insulating layer 21 is greater than 0 μm and not more than 100 μm. Considering the ease of the process of forming vias in the first insulating layer 21 and the ease of handling during manufacturing, it is more preferable that the thickness is not less than 10 μm and not more than 50 μm.

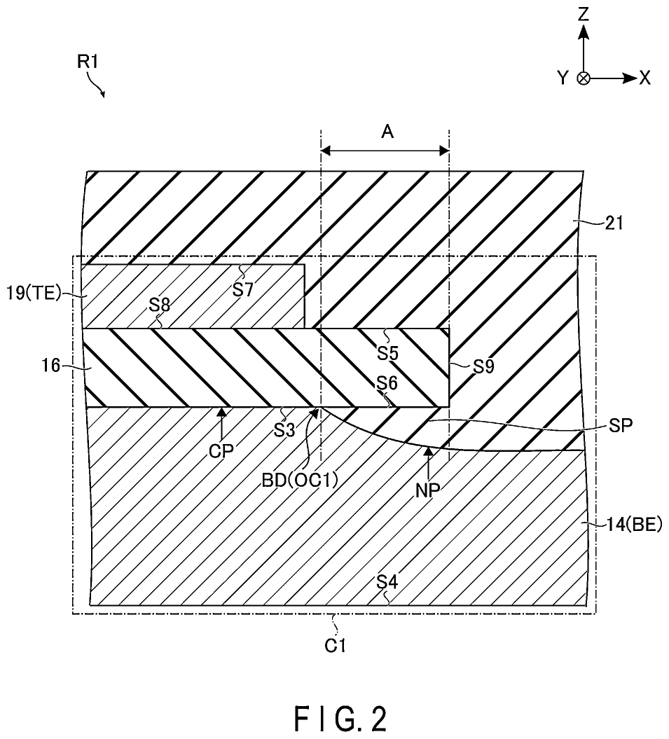

FIG. 2 is a cross-sectional view in which part (region R1) of the wiring substrate 1 depicted in FIG. 1 is shown in an enlarged scale. It should be noted that in FIG. 2, illustration of the first seed layer 13, the second adhesion layer 15, the third adhesion layer 17, and the second seed layer 18 is omitted.

As shown in FIG. 2, below the end portion of the dielectric layer 16, there is a portion where the first insulating layer 21 is embedded between the dielectric layer 16 and the first conductive layer 14 (bottom electrode BE). This portion is, for example, a portion where the first conductive layer 14 is removed by side etching during the etching of the first seed layer 13 (hereinafter referred to as “side-etched portion SP”). FIG. 2 shows a state in which the first insulating layer 21 is embedded in the side-etched portion SP in a subsequent process.

In other words, the third face S3 of the first conductive layer 14 that faces the sixth face S6 of the dielectric layer 16 includes a contact portion CP that is in contact with the sixth face S6 of the dielectric layer 16 and a non-contact portion NP that is not in contact with the sixth face S6 of the dielectric layer 16. That is, the first conductive layer 14 and the dielectric layer 16 are in partial contact with each other. Therefore, the first conductive layer 14 (bottom electrode BE) is thicker in the contact portion CP than in the non-contact portion NP. In the description below, the boundary between the contact portion CP and the non-contact portion NP on the third face S3 of the first conductive layer 14 will be referred to as “boundary BD” or “outer circumference OC1 of the contact portion CP.” Further, the distance between the outer circumference OC1 of the contact portion CP and the end face S9 of the dielectric layer 16 will be referred to as “distance A” or “side etching amount A.”

In this specification, the contact portion CP of the first conductive layer 14 refers to that portion of the third face S3 of the first conductive layer 14 which is in direct contact with the sixth face S6 of the dielectric layer 16 in a case where the second adhesion layer 15 is not present, and refers to that portion of the third face S3 of the first conductive layer 14 which is in direct contact with the second adhesion layer 15 in a case where the second adhesion layer 15 is present. Further, the state in which the first conductive layer 14 and the dielectric layer 16 are in contact with each other refers to the state in which the first conductive layer 14 and the dielectric layer 16 are in direct contact with each other in a case where the second adhesion layer 15 is not present, and refers to the state in which the first conductive layer 14 and the second adhesion layer 15 are in direct contact with each other and the dielectric layer 16 and the second adhesion layer 15 are in direct contact with each other in a case where the second adhesion layer 15 is present.

In this specification, the non-contact portion NP of the first conductive layer 14 refers to that portion of the third face S3 of the first conductive layer 14 which is not in direct contact with the sixth face S6 of the dielectric layer 16 in a case where the second adhesion layer 15 is not present, and refers to that portion of the third face S3 of the first conductive layer 14 which is not in direct contact with the second adhesion layer 15 in a case where the second adhesion layer 15 is present. Further, the state in which the first conductive layer 14 and the dielectric layer 16 are not in contact with each other refers to the state in which the first conductive layer 14 and the dielectric layer 16 are not in direct contact with each other in a case where the second adhesion layer 15 is not present, and refers to the state in which the first conductive layer 14 and the second adhesion layer 15 are not in direct contact with each other and the dielectric layer 16 and the second adhesion layer 15 are in direct contact with each other in a case where the second adhesion layer 15 is present.

In a case where the first seed layer 13 is etched, side etching of the first conductive layer 14 can be prevented by adjusting the etching amount of the first seed layer 13 in accordance with the thickness of the first seed layer 13. However, considering variations in the thickness of the first seed layer 13, there may be locations where the first seed layer 13 cannot be completely removed. In the present embodiment, therefore, the etching of the first seed layer 13 is performed in consideration of the variations in the thickness of the first seed layer 13 by adjusting the etching amount of the first seed layer 13 such that the side etching amount A of the first conductive layer 14 is greater than the thickness of the first seed layer 13. Making adjustment in this way ensures good quality.

For example, in a case where the thickness of the first seed layer 13 is denoted by T, the side etching amount A of the first conductive layer 14 is expressed by the following formulas:

A=T×1.2 to 40

1.2≤A/T≤40

That is, it is preferable that the side etching amount A of the first conductive layer 14 is not less than 1.2 times of the thickness T of the first seed layer 13 and not more than 40 times of the thickness T of the first seed layer 13. In other words, it is preferable to adjust the etching amount of the first seed layer 13 in such a manner as to satisfy the above formulas. Thus, the outer circumference OC1 of the contact portion CP of the first conductive layer 14 is located inward of the end face S9 of the dielectric layer 16, for example, in a range of not less than 1.2 times of the thickness T of the first seed layer 13 and not more than 40 times of the thickness T of the first seed layer 13. In a case where the side etching amount A is less than 1.2 times of the etching amount of the first seed layer 13, there is a possibility that the film of the first seed layer 13 remains at some portion. In a case where the side etching amount A exceeds 40 times of the etching amount of the first seed layer 13, the resin may not enter the side-etched portion SP in a sufficient amount during formation of the first insulating layer 21, and voids may be generated in the side-etched portion SP. In such a case, the adhesion between the capacitor C1 and the first insulating layer 21 may deteriorate. In addition, since the contact portion between the dielectric layer 16 and the first conductive layer 14 is small, the application of slight stress may cause cracks in the dielectric layer 16.

It is preferable that the side etching amount A of the first conductive layer 14 is, for example, greater than 0 μm and not more than 12 μm. In a case where the side etching amount A is 0 μm, there may be a portion where the film of the first seed layer 13 remains, as described above. In a case where the side etching amount A exceeds 12 μm, voids may be generated in the side-etched portion SP, and the adhesion between the capacitor C1 and the first insulating layer 21 may deteriorate, as described above. Furthermore, cracks may occur in the dielectric layer 16, as described above.

The insulating resin used for the first insulating layer 21 may include a filler. In a case where the insulating resin includes a filler, the maximum particle size of the filler is preferably not more than the thickness T of the first seed layer 13. In a case where the maximum particle size of the filler is larger than the thickness T of the first seed layer 13, the filler may not enter the side-etched portion SP, resulting in insufficient filling of the insulating resin. Thus, voids will be generated in the side-etched portion SP, and the adhesion between the capacitor C1 and the first insulating layer 21 may deteriorate. In addition, since the contact portion between the dielectric layer 16 and the first conductive layer 14 is small, the application of slight stress may cause cracks in the dielectric layer 16.

On the other hand, in a case where the insulating resin does not include a filler, the fluidity of the insulating resin is superior to that of an insulating resin including a filler. Thus, the filling rate of the insulating resin in the side-etched portion SP is higher than the filling rate of the insulating resin including a filler. Therefore, sufficient adhesion between the capacitor C1 and the first insulating layer 21 is ensured, and the occurrence of cracks in the dielectric layer 16 can be suppressed.

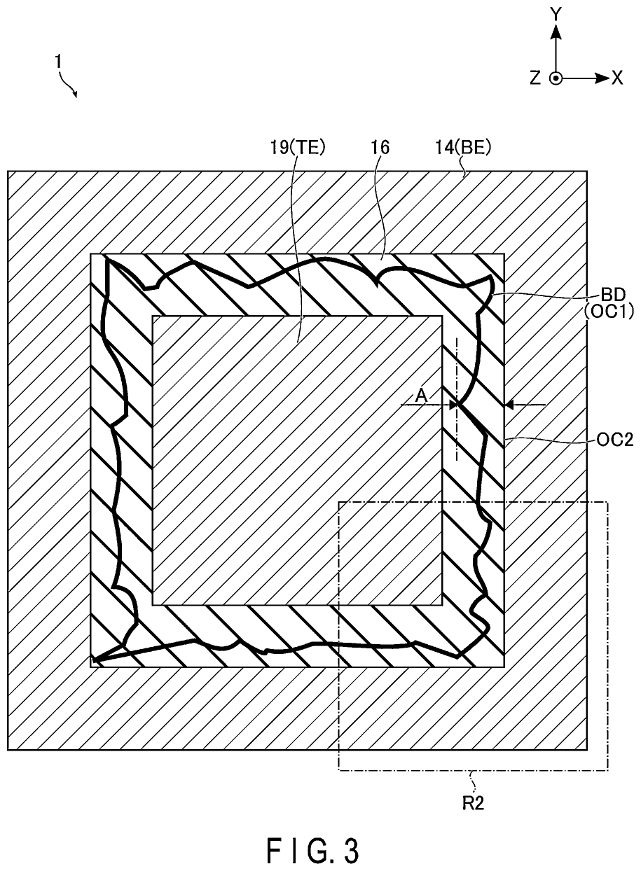

FIG. 3 is a top view of the wiring substrate 1 depicted in FIG. 1. In FIG. 3, the outer circumference OC1 of the contact portion CP of the first conductive layer 14 is shown by solid lines. In FIG. 3, illustration of the glass substrate 11, the first adhesion layer 12, the first seed layer 13, the second adhesion layer 15, the third adhesion layer 17, the second seed layer 18, and the first insulating layer 21 is omitted.

As shown in FIG. 3, the outer circumference OC1 of the contact portion CP of the first conductive layer 14 has a sawtooth shape (irregularities) as viewed from above (as viewed in the Z direction). That is, the outer circumference OC1 of the contact portion CP is not a straight line as viewed from above. In other words, the distance A between the outer circumference OC1 of the contact portion CP and the end face S9 of the dielectric layer 16 is not constant. Thus, at the time of the formation of the first insulating layer 21, in the side-etched portion SP, resin enters the recessed portions of the irregular outer circumference OC1 of the contact portion CP having a sawtooth shape. Therefore, the anchor effect allows the resin to firmly adhere to the first conductive layer 14 and the dielectric layer 16.

The dielectric layer 16 may be made of a transparent material. Examples of the transparent material include silicon nitride, silicon oxide, etc. In a case where a transparent material is used for the dielectric layer 16, the boundary BD (the outer circumference OC1 of the contact portion CP) can be confirmed from above.

For example, a serial sectioning method is known in which continuous cross-sectional slicing and cross-sectional observation of a sample are alternately performed using a microtome, a focused ion beam (FIB), etc., and two-dimensional continuous images obtained thereby are reconstructed in three dimensions. By this method, it can be confirmed that the boundary BD (the outer circumference OC1 of the contact portion CP) has a sawtooth shape (not a straight line) as viewed from above.

As shown in FIG. 3, the outer circumference OC2 of the sixth face S6 of the dielectric layer 16 has a rectangular shape. Since this suppresses variations in the dielectric constant, the electrostatic capacitance of the capacitor C1 is stabilized.

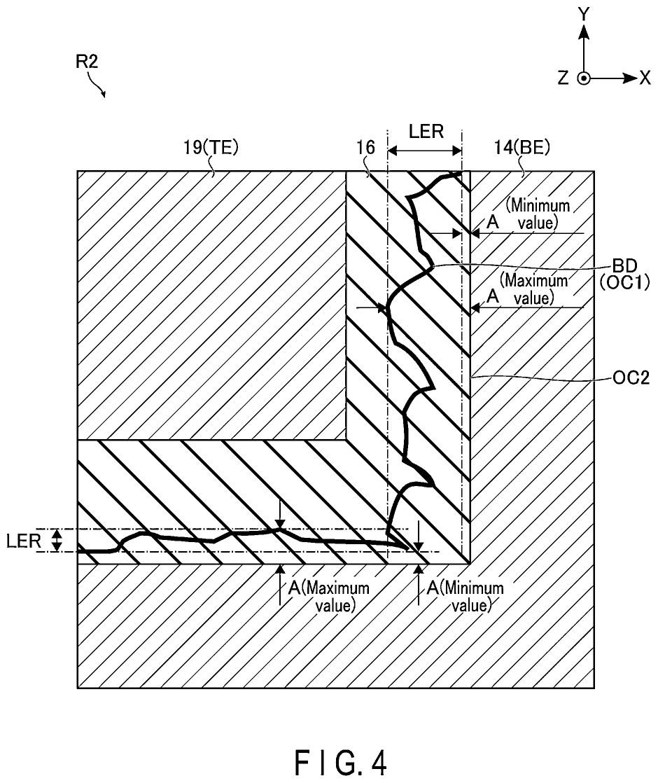

FIG. 4 is a top view in which part (region R2) of the wiring substrate 1 depicted in FIG. 3 is shown in an enlarged scale. In FIG. 4, illustration of the glass substrate 11, the first adhesion layer 12, the first seed layer 13, the second adhesion layer 15, the third adhesion layer 17, the second seed layer 18, and the first insulating layer 21 is omitted.

The difference between the maximum value and the minimum value of the side etching amount A of the first conductive layer 14 in the X direction, and the difference between the maximum value and the minimum value of the side etching amount A of the first conductive layer 14 in the Y direction are each defined as an LER (Line Edge Roughness) of the contact portion CP of the first conductive layer 14. For example, it is preferable that the LER is not less than 1000 nm and not more than 5000 nm. In a case where the LER is less than 1000 nm, an anchor effect cannot be obtained, and the adhesion between the first insulating layer 21, and the first conductive layer 14 and the dielectric layer 16 is insufficient. Thus, peeling may occur between the first insulating layer 21, and the first conductive layer 14 and the dielectric layer 16. In a case where the LER exceeds 5000 nm, the parasitic capacitance of the capacitor C1 may vary.

### <1.2> Manufacturing Method of Wiring Substrate

The wiring substrate 1 described above can be manufactured, for example, by the method described below.

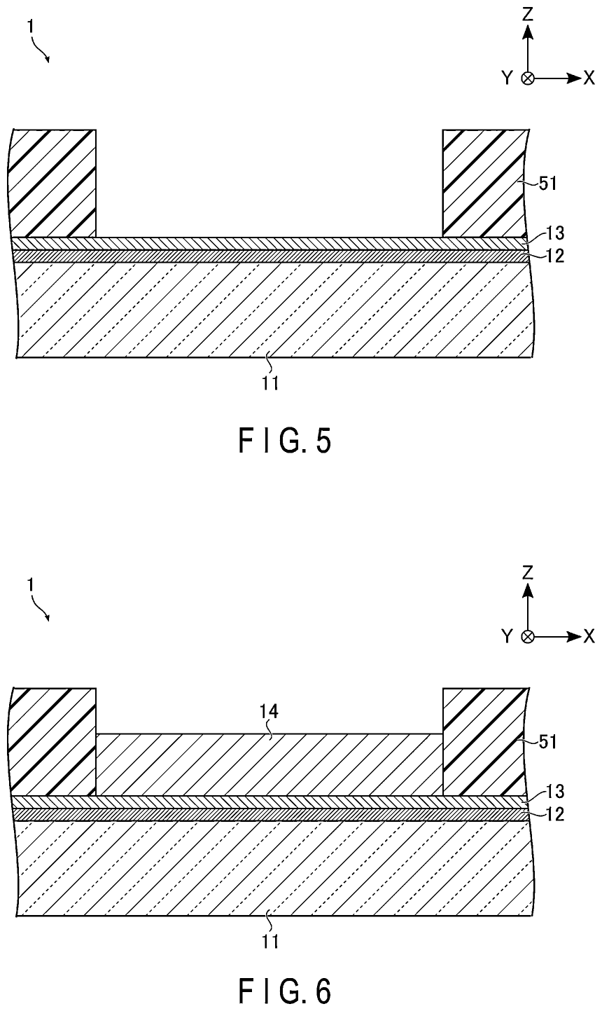

FIG. 5 to FIG. 11 and FIG. 13 are cross-sectional views each illustrating one step performed in the method for manufacturing the wiring substrate depicted in FIG. 1.

### <1.2.1> First Step

Although not shown in FIG. 5, in this method, at least one through hole is first formed in the glass substrate 11, extending from the front surface to the back surface of the glass substrate 11. As the glass substrate 11, a glass material made by the method described above is used. The thickness of the glass substrate 11 can be, for example, in the range of greater than 0 mm and not more than 1 mm. The through hole is formed, for example, by laser beam irradiation. The formed through-hole has any of the shapes described above.

### <1.2.2> Second Step

Next, as shown in FIG. 5, a first adhesion layer 12 and a first seed layer 13 are formed in this order on the surface of the glass substrate 11 and in the through hole. Thus, the first seed layer 13 is formed above the glass substrate 11 and inside the through hole.

The first adhesion layer 12 is formed, for example, by a sputtering method. As the first adhesion layer 12, the above-mentioned material, for example, titanium, is used. The thickness of the first adhesion layer 12 formed on the glass substrate 11 can be, for example, in the range of not less than 10 nm and not more than 1000 nm.

The first seed layer 13 is formed, for example, by a sputtering method and electroless plating. For example, the above-mentioned material, such as copper, is formed by a sputtering method, and then a metal layer (electroless plating layer) is additionally formed by electroless plating. In a case where the first seed layer 13 is formed only by a sputtering method, there is a possibility that the metal film cannot be uniformly formed on the inner wall of the through hole. For this reason, it is preferable to first form copper by a sputtering method and then strengthen the metal layer by electroless plating. Examples of electroless plating include electroless copper plating, electroless nickel plating, etc., but electroless nickel plating is preferably performed because it exhibits good adhesion to glass, or titanium and copper.

In a case where the electroless nickel plating layer is too thick, it may be difficult to form fine wiring. In addition, the adhesion may deteriorate due to an increase in the film stress. Therefore, the thickness of the electroless nickel plating layer can be set in the range of greater than 0 μm and not more than 1 μm. The thickness of the electroless nickel plating layer is more preferably greater than 0 μm and not more than 0.5 μm, and even more preferably greater than 0 μm and not more than 0.3 μm.

The electroless nickel plating layer may include phosphorus, which is a eutectoid substance derived from the reducing agent, and sulfur, lead, bismuth, etc., which are included in the electroless nickel plating solution.

The thickness T of the first seed layer 13 formed on the first adhesion layer 12 can be, for example, in the range of not less than 50 nm and not more than 5000 nm.

In a case where the adhesion between the glass substrate 11 and the first seed layer 13 is sufficient, the first adhesion layer 12 need not be provided. In this case, the first seed layer 13 is formed on the surface of the glass substrate 11 and inside the through hole in the present step.

### <1.2.3> Third Step

Next, as shown in FIG. 5, a mask pattern (hereinafter also referred to as a “mask” as well) is formed on the first seed layer 13. The mask pattern is formed, for example, by providing a resist layer 51 on the first seed layer 13, aligning the resist layer 51 such that the portion where the first conductive layer 14 is to be provided is exposed, and performing pattern exposure and development to the resist layer 51 using a photolithography method. The formed mask pattern (resist layer 51) has an opening at a position corresponding to the first conductive layer 14. Examples of the resist layer 51 include a negative dry film resist, a negative liquid resist, and a positive liquid resist, but it is preferably to use the negative dry film resist because the resist layer 51 can be formed easily and at low cost.

The thickness of the resist layer 51 formed on the first seed layer 13 depends on the thickness of the first conductive layer 14, but can be, for example, in the range of not less than 5 μm and not more than 25 μm. In a case where the thickness of the resist layer 51 is less than 5 μm, the electrolytic plating layer to be used as the first conductive layer 14 cannot be formed to have a thickness of not less than 5 μm, and the connection reliability of the circuit may deteriorate. In a case where the thickness of the resist layer 51 exceeds 25 μm, it is difficult to form fine wiring with a pitch of not more than 30 μm.

### <1.2.4> Fourth Step

Next, as shown in FIG. 6, by supplying power to the first seed layer 13 and immersing it in a plating solution, a metal layer (electrolytic plating layer) to be used as the first conductive layer 14 is formed on the first seed layer 13 on which the mask pattern (resist layer 51) is not formed (on part of the first seed layer 13). The electrolytic plating is, for example, electrolytic copper plating. The thickness of the first conductive layer 14 formed on the first seed layer 13 can be, for example, in the range of not less than 3 μm and not more than 30 μm.

### <1.2.5> Fifth Step

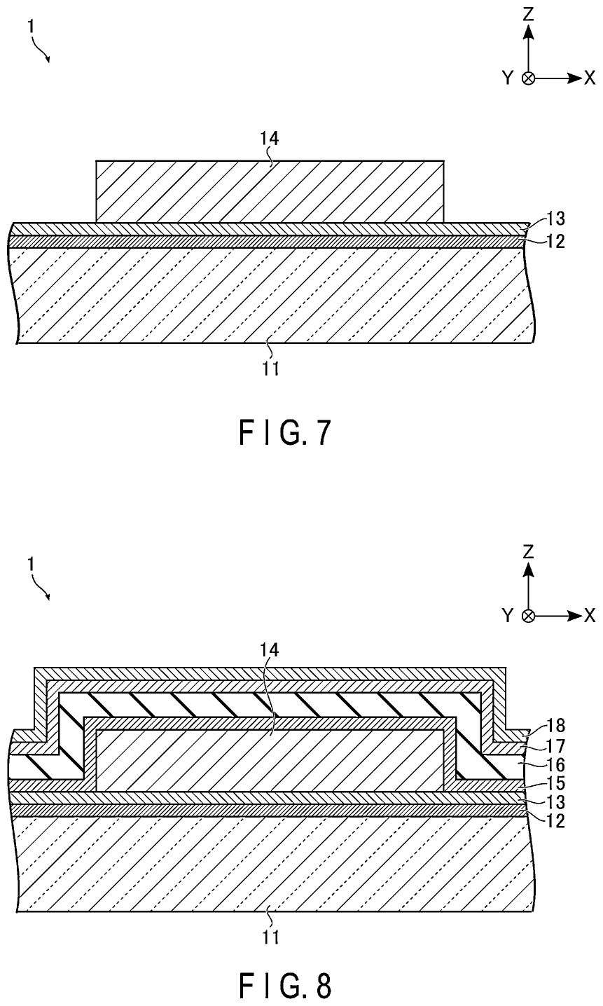

Next, as shown in FIG. 7, the resist layer 51 is removed to expose part of the first seed layer 13. The method for removing the resist layer 51 is not limited to any specific method; for example, the resist layer 51 can be removed by peeling with an alkaline aqueous solution.

### <1.2.6> Sixth Step

Next, as shown in FIG. 8, a second adhesion layer 15 is first formed in such a manner as to cover the first seed layer 13 and the first conductive layer 14, and then a dielectric layer 16, a third adhesion layer 17 and a second seed layer 18 are formed on the second adhesion layer 15 in this order. Thus, the dielectric layer 16 is formed above the first seed layer 13 and the first conductive layer 14. The second seed layer 18 is formed above the dielectric layer 16. Methods for forming the second adhesion layer 15, the dielectric layer 16, the third adhesion layer 17, and the second seed layer 18 include a vacuum evaporation method, a sputtering method, an ion plating method, an MBE (Molecular Beam Epitaxy) method, a laser ablation method, a CVD method, etc., but these are not restrictive.

The second adhesion layer 15 is formed by a method similar to that of the first adhesion layer 12. The material of the second adhesion layer 15 and the thickness of the second adhesion layer 15, which is formed to cover the first seed layer 13 and the first conductive layer 14, are similar to those of the first adhesion layer 12.

The dielectric layer 16 is formed, for example, by a CVD method. As the dielectric layer 16, the above-mentioned material, for example, silicon nitride, is used. The thickness of the dielectric layer 16 formed on the second adhesion layer 15 can be, for example, in the range of not less than 10 nm and not more than 5000 nm.

The third adhesion layer 17 is formed by a method similar to that of the first adhesion layer 12. The material of the third adhesion layer 17 and the thickness of the third adhesion layer 17 formed on the dielectric layer 16 are similar to those of the first adhesion layer 12.

The second seed layer 18 is formed by a method similar to that of the first seed layer 13. The material of the second seed layer 18 and the thickness of the second seed layer 18 formed on the third adhesion layer 17 are similar to those of the first seed layer 13.

In the present embodiment, the second adhesion layer 15, the dielectric layer 16, the third adhesion layer 17 and the second seed layer 18 are formed without removing unnecessary portions of the first seed layer 13 and first adhesion layer 12 after the first conductive layer 14 is formed. Therefore, at the time of forming the second seed layer 18, abnormalities in the adhesion property of the second seed layer 18 can be suppressed. As a result, the second conductive layer 19 can also be formed in a stable manner.

In a case where the adhesion between the first conductive layer 14 and the dielectric layer 16 is sufficient, the second adhesion layer 15 need not be provided. In this case, the dielectric layer 16 is formed in the present step in such a manner as to cover the first seed layer 13 and the first conductive layer 14. Further, in a case where the adhesion between the dielectric layer 16 and the second seed layer 18 is sufficient, the third adhesion layer 17 need not be provided. In this case, the second seed layer 18 is formed on the dielectric layer 16 in the present step.

### <1.2.7> Seventh Step

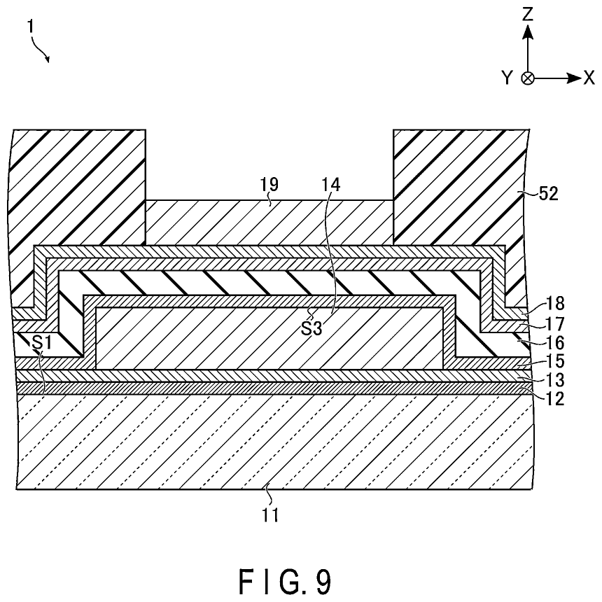

Next, as shown in FIG. 9, a mask pattern is formed on the second seed layer 18. The mask pattern is formed, for example, by providing a resist layer 52 on the second seed layer 18, aligning the resist layer 52 such that the portion where the second conductive layer 19 is to be provided is exposed, and performing pattern exposure and development to the resist layer 52 using a photolithography method. The formed mask pattern (resist layer 52) has an opening at a position corresponding to the second conductive layer 19. The opening in the resist layer 52 is formed such that its cross-sectional area (the area of the cross section parallel to the first face S1 of the glass substrate 11) is smaller than the size of the third face S3 of the first conductive layer 14. As the resist layer 52, resist similar to that of the resist layer 51 is used.

### <1.2.8> Eighth Step

Next, as shown in FIG. 9, by supplying power to the second seed layer 18 and immersing it in a plating solution, a metal layer (electrolytic plating layer) to be used as the second conductive layer 19 is formed on the second seed layer 18 on which the mask pattern (resist layer 52) is not formed (on part of the second seed layer 18). The electrolytic plating is, for example, electrolytic copper plating. The thickness of the second conductive layer 19 formed on the second seed layer 18 can be, for example, in the range of not less than 3 μm and not more than 30 μm.

### <1.2.9> Ninth Step

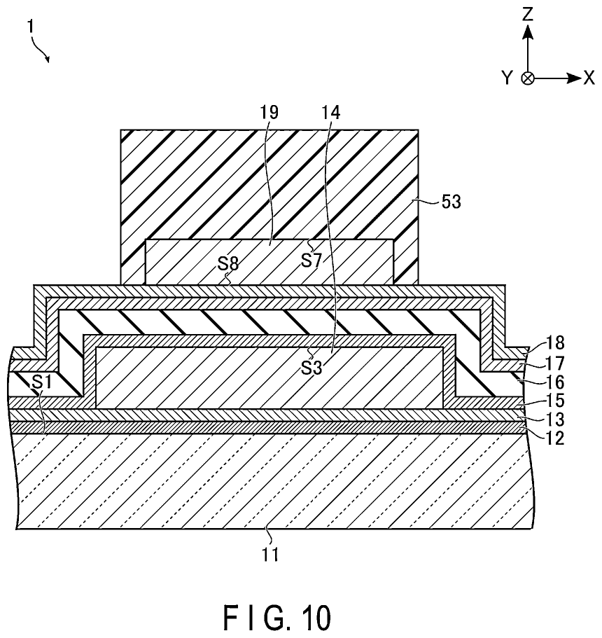

Next, as shown in FIG. 10, the resist layer 52 is removed to expose part of the second seed layer 18. The method for removing the resist layer 52 is similar to the method for removing the resist layer 51.

### <1.2.10> 10th Step

Next, as shown in FIG. 10, a mask pattern is formed on the second seed layer 18 and the second conductive layer 19. The mask pattern can be formed using the resist layer 53, in a manner similar to that of the mask pattern described above. The formed mask pattern (resist layer 53) covers part of the second seed layer 18, and the second conductive layer 19. The resist layer 53 is formed such that its cross-sectional area (the area of a cross section parallel to the first face S1 of the glass substrate 11) is smaller than the size of the third face S3 of the first conductive layer 14 and is larger than the sizes of the seventh face S7 and the eighth face S8 of the second conductive layer 19. As the resist layer 53, resist similar to that of the resist layer 51 is used.

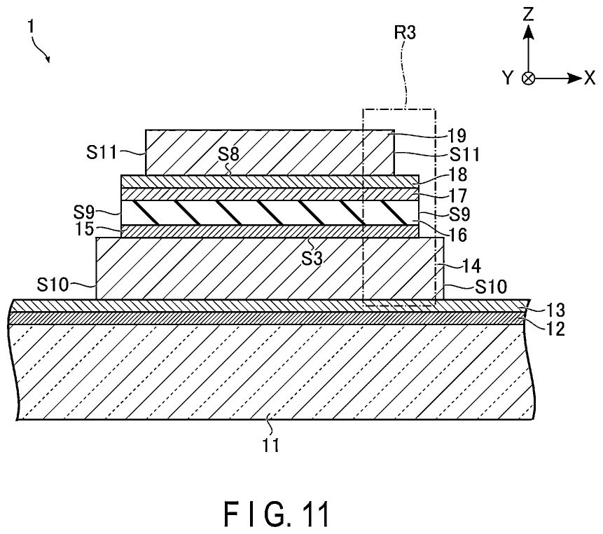

Next, as shown in FIG. 11, unnecessary portions of the second seed layer 18, the third adhesion layer 17, the dielectric layer 16, and the second adhesion layer 15 are removed by etching. As this removal method, chemical etching or dry etching can be used. Different removal methods may be employed for the respective layers, or the same removal method may be employed for all layers. Since the resist layer 53 is formed such that its cross-sectional area has the above-mentioned size, the second seed layer 18, the third adhesion layer 17, the dielectric layer 16, and the second adhesion layer 15 are etched as shown in FIG. 11. For example, each of the end faces of the second seed layer 18, third adhesion layer 17, dielectric layer 16, and second adhesion layer 15 is located inward of the end face S10 of the first conductive layer 14 and is located outward of the end face S11 of the second conductive layer 19. That is, the dielectric layer 16 is formed to have a size smaller than that of the first conductive layer 14.

The removal of unnecessary portions of the second seed layer 18 and the third adhesion layer 17 need not be performed in the present step. For example, prior to the present step, the unnecessary portions of the second seed layer 18 and the third adhesion layer 17 may be removed using the second conductive layer 19 as a mask.

### <1.2.11> 11th Step

Next, as shown in FIG. 11, the resist layer 53 is removed to expose part of the second seed layer 18, and the second conductive layer 19. The method for removing the resist layer 53 is similar to the method for removing the resist layer 51.

### <1.2.12> 12th Step

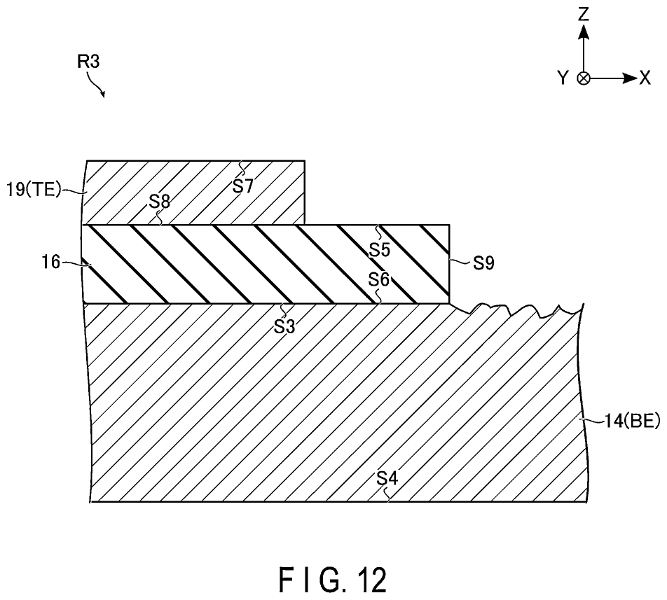

Next, the end portion (exposed portion) of the surface of the first conductive layer 14 is etched. Thus, as shown in FIG. 12, roughness is generated at the end portion of the surface of the first conductive layer 14. In the description below, the etching treatment of the present step will be referred to as “seed layer etching pre-treatment” as well. FIG. 12 is a cross-sectional view in which part (region R3) of the cross-sectional view depicted in FIG. 11 is shown in an enlarged scale. It should be noted that in FIG. 12, illustration of the first seed layer 13, the second adhesion layer 15, the third adhesion layer 17, and the second seed layer 18 is omitted.

In the present step, roughness whose surface roughness is in the range of not less than 30 nm and not more than 70 nm is generated at the end portion of the surface of the first conductive layer 14 by the etching performed. For example, the concentration of the etching solution used for removal of the first seed layer 13 in the 13th step, which will be described later, the process time and the process temperature are determined for the etching such that the surface roughness of the first conductive layer 14 is in the range of not less than 30 nm and not more than 70 nm. In a case where the surface roughness is less than 30 nm, the anchor effect will not be obtained during the formation of the first insulating layer 21 in the 14th step, which will be described later, and the adhesion between the first insulating layer 14, and the dielectric layer 16 and the first insulating layer 21 is weak, so that the first insulating layer 21 may easily peel off. In a case where the surface roughness exceeds 70 nm, side etching tends to occur at the interface between the dielectric layer 16 and the first conductive layer 14, so that the contact area between the dielectric layer 16 and the first conductive layer 14 is small. Stress is concentrated on the contact area. Therefore, the adhesion between the dielectric layer 16 and the first conductive layer 14 is weak, and the dielectric layer 16 may easily peel off. In this specification, the surface roughness corresponds to arithmetic mean roughness Ra. The arithmetic mean roughness Ra is a surface quality parameter defined by JIS B0601:2001.

### <1.2.13> 13th Step

Next, unnecessary portions of the first seed layer 13 and the first adhesion layer 12 are removed by etching. As this removal method, chemical etching or dry etching can be used. Different removal methods may be employed for the respective layers, or the same removal method may be employed for all layers. For example, the electroless plating layer and copper layer of the first seed layer 13, and the first adhesion layer 12 can be sequentially removed by chemical etching, but the removal method is not limited to this. The kind of etching solution is appropriately selected depending on the type of metal to be removed.

In the present step, the first seed layer 13 is etched such that the side etching amount A of the first conductive layer 14 is in the range of not less than 1.2 times of the thickness T of the first seed layer 13 and not more than 40 times thereof. For example, the first seed layer 13 can be etched in the range of not less than 1.2 times of the thickness T of the first seed layer 13 and not more than 40 times thereof.

In the present step, as shown in FIG. 2, the first conductive layer 14 is side-etched to form a side-etched portion SP. Since roughness is generated at the end portion of the surface of the first conductive layer 14 in the 12th step, the etching solution does not uniformly enter the region under the end portion of the dielectric layer 16 during removal of the first seed layer 13 of the present step. As shown in FIG. 3, therefore, the outer circumference OC1 of the contact portion CP of the first conductive layer 14 has a sawtooth shape.

### <1.2.14> 14th Step

Next, by use of a vacuum laminator, a roll coater, etc., a first insulating layer 21 is formed in such a manner as to cover the surface of the glass substrate 11, the first adhesion layer 12, the first seed layer 13, the first conductive layer 14, the second adhesion layer 15, the dielectric layer 16, the third the adhesion layer 17, the second seed layer 18, and the second conductive layer 19. At this time, the first insulating layer 21 is embedded in a portion (side-etched portion SP) where a portion of the first conductive layer 14 is removed as a result of the removal of the first seed layer 13. In the side-etched portion SP, resin enters the recessed portions of the irregular outer circumference OC1 of the sawtooth-shape contact portion CP. Therefore, the anchor effect allows the resin to firmly adhere to the first conductive layer 14 and the dielectric layer 16. Thus, the structure of the wiring substrate 1 shown in FIG. 1 (the wiring substrate 1 in which the capacitor C1 is formed on the surface of glass substrate 11) is obtained. As the first insulating layer 21, the above-mentioned material, for example, an insulating resin, is used. The thickness of the first insulating layer 21 can be, for example, in the range of greater than 0 μm and not more than 100 μm.

### <1.2.15> 15th Step

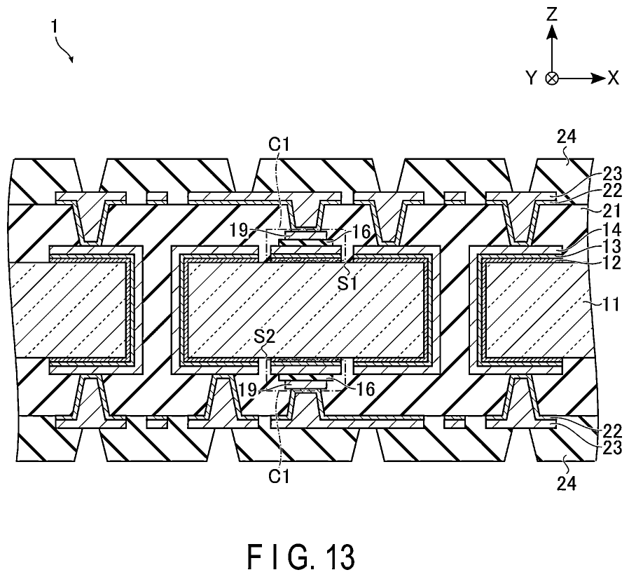

Next, as shown in FIG. 13, vias are formed in the first insulating layer 21 at the positions of the first conductive layer 14 and the second conductive layer 19.

Next, a third seed layer 22 is formed in such a manner as to cover the upper face of the first insulating layer 21, the sidewalls of the vias provided in the first insulating layer 21, and those portions of the first conductive layer 14 and second conductive layer 19 which are exposed as a result of the formation of the vias. The third seed layer 22 is formed in a manner similar to that of the first seed layer 13. The material of the third seed layer 22 is similar to that of the first seed layer 13. It should be noted that before the third seed layer 22 is formed, an adhesion layer may be formed to cover the upper face of the first insulating layer 21, the sidewalls of the vias provided in the first insulating layer 21, and those portions of the first conductive layer 14 and second conductive layer 19 which are exposed as a result of the formation of the vias.

Next, a mask pattern is formed on the third seed layer 22. The mask pattern is formed, for example, by providing a resist layer on the third seed layer 22, aligning the resist layer such that the portion where the third conductive layer 23 is to be provided is exposed, and performing pattern exposure and development to the resist layer using a photolithography method. The formed mask pattern (resist layer) has an opening at a position corresponding to the third conductive layer 23.

Next, by supplying power to the third seed layer 22 and immersing it in a plating solution, a metal layer (electrolytic plating layer) to be used as the third conductive layer 23 is formed on the third seed layer 22 on which the mask pattern (resist layer) is not formed. As an example of electrolytic plating, for example, electrolytic copper plating is preferred because it is simple, inexpensive, and provides good electrical conductivity. The third conductive layer 23 may be formed not only by electrolytic copper plating but also by electrolytic nickel plating, electrolytic chromium plating, electrolytic palladium plating, electrolytic gold plating, electrolytic rhodium plating, electrolytic iridium plating, or the like.

Like the first conductive layer 14, the thickness of the third conductive layer 23 (the thickness of electrolytic copper plating) is preferably, for example, not less than 3 μm and not more than 30 μm, more preferably not less than 5 μm and not more than 25 μm, and still more preferably not less than 10 μm and not more than 20 μm.

Next, the resist layer is removed to expose part of the third seed layer 22. The method for removing the resist layer is similar to the method for removing the resist layer 51.

Next, unnecessary portions (exposed portions) of the third seed layer 22 are removed by etching. The method for removing the third seed layer 22 is similar to the method for removing the first seed layer 13.

Next, a second insulating layer 24 is formed in such a manner as to cover the first insulating layer 21, the third seed layer 22, and the third conductive layer 23. The second insulating layer 24 is formed by a method similar to that of the first insulating layer 21. The material of the second insulating layer 24 is similar to that of the first insulating layer 21.

Next, a via is formed in the second insulating layer 24 at the position of the third conductive layer 23.

As a result of this step, the third conductive layer 23 is provided above a portion of the first conductive layer 14, the second conductive layer 19, and a portion of the first insulating layer 21. The third conductive layer 23 includes a via portion in which a conductive material is embedded in the via provided in the first insulating layer 21, a pad portion exposed at the position of the via in the second insulating layer 24, and wiring portions other than these portions. The via portion of the third conductive layer 23 couples the wiring portion, which is the first conductive layer 14, or the top electrode of the capacitor C1, which is the second conductive layer 19, to the pad portion of the third conductive layer 23. In other words, the third conductive layer 23 is used as a wiring for forming a circuit and a lead wiring of the capacitor C1. It should be noted that the pad portion of the third conductive layer 23 may be formed as an external connection terminal.

The second to fifteenth steps are performed for the back surface of the glass substrate 11 as well, in order to form a first adhesion layer 12, a first seed layer 13, a first conductive layer 14, a second adhesion layer 15, a dielectric layer 16, a third adhesion layer 17, a second seed layer 18, a second conductive layer 19, a first insulating layer 21, a third seed layer 22, a third conductive layer 23, and a second insulating layer 24. Thus, the structure of the wiring substrate 1 shown in FIG. 13 is obtained. It should be noted that in FIG. 13, illustration of the second adhesion layer 15, the third adhesion layer 17, and the second seed layer 18 is omitted.

The circuit and stacked structure on the wiring substrate 1 can be formed using a known semi-additive method or a subtractive method.

External connection terminals can also be formed after the formation of the wiring substrate 1. Solder balls can be formed on the external connection terminals.

In the wiring substrate 1, the circuit, the stacked structure, the external connection terminals, and the solder balls may be provided on one side of the glass substrate 11, or may be provided on both sides of the glass substrate 11. A semiconductor chip and chip components (resistors, capacitors, inductors, etc.) may be mounted on the wiring substrate 1.

### <1.3> Advantageous Effect

The above-mentioned techniques produce advantageous effects described below, for example.

According to the present embodiment, the end portions of the surface of the first conductive layer 14 are first roughened by etching, and then unnecessary portions of the first seed layer 13 are removed by etching. Thereafter, the capacitor C1 is covered with the first insulating layer 21.

After unnecessary portions of the first seed layer 13 are removed by etching, the first conductive layer 14 is side-etched isotropically. Since roughness exists at the end portions of the surface of the first conductive layer 14 at the time, the etching solution does not uniformly enter the region under the end portions of the dielectric layer 16. Thus, the side etching amount A of the first conductive layer 14 varies depending upon positions. Therefore, the outer circumference OC1 of the contact portion CP of the first conductive layer 14 has a sawtooth shape.

In a case where the capacitor C1 is covered with the first insulating layer 21, the resin also enters the side-etched portion SP. The outer circumference OC of the contact portion CP has a sawtooth shape, so that in the side-etched portion SP the resin enters the recessed portions of the irregular outer circumference OC1 of the contact portion CP. Therefore, the anchor effect allows the resin to firmly adhere to the first conductive layer 14 and the dielectric layer 16.

Therefore, according to the present embodiment, sufficient adhesion between the capacitor C1 and the first insulating layer 21 can be ensured, and the occurrence of peeling can be suppressed between the capacitor C1 and the first insulating layer 21.

### <2> Second Embodiment

The second embodiment of the present invention is similar to the first embodiment except that the wiring substrate is manufactured in the method described below.

### <2.1> Manufacturing Method of Wiring Substrate

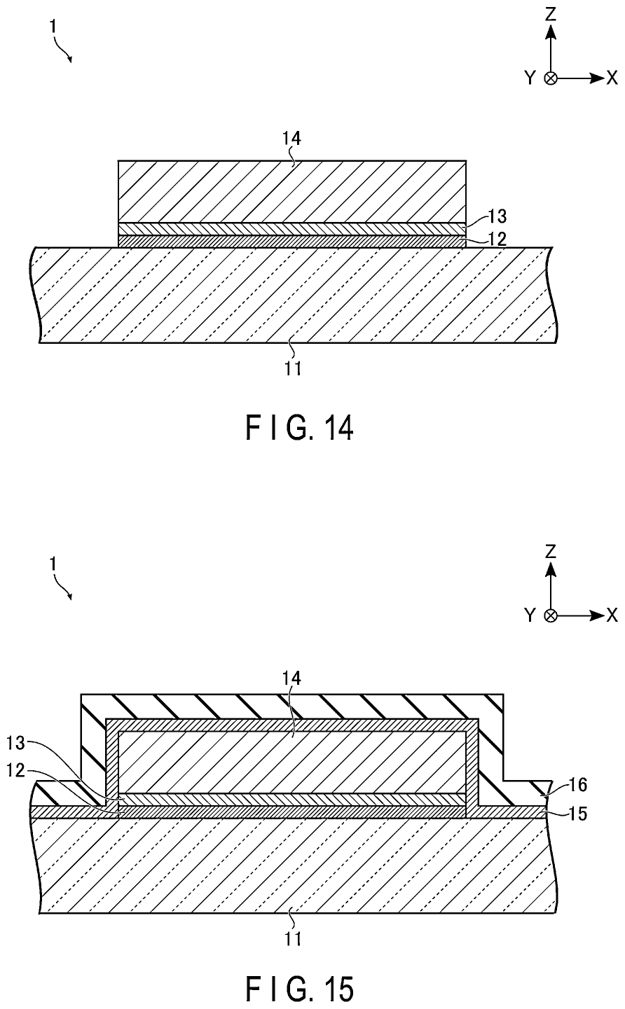

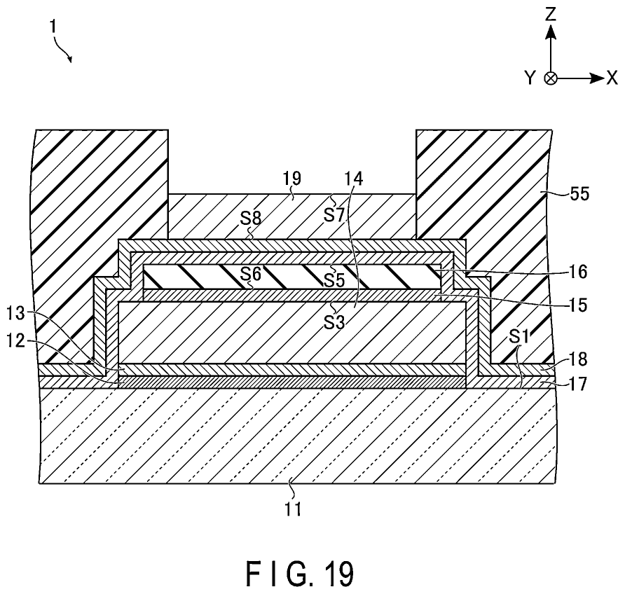

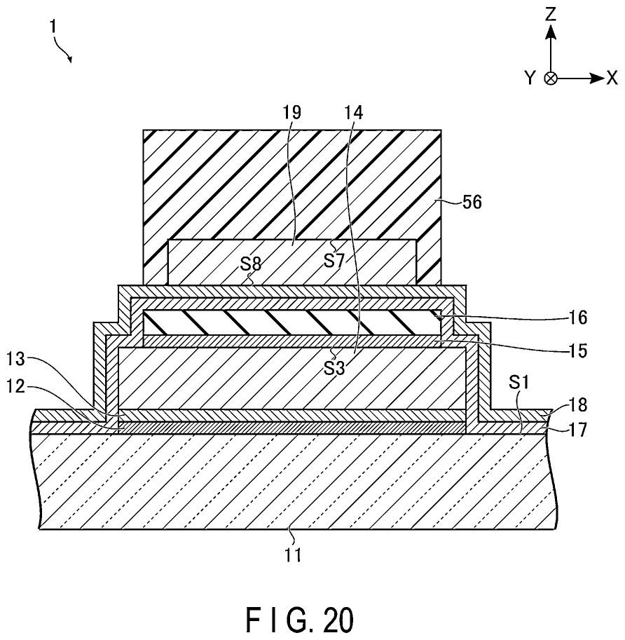

FIG. 14 to FIG. 17, FIG. 19 and FIG. 20 are cross-sectional views each showing one step performed in the manufacturing method of a wiring substrate according to the second embodiment of the present invention.

In the method for manufacturing the wiring substrate according to the second embodiment, the 6th to 14th steps of the first embodiment are replaced with 16th to 26th steps. In the description below, reference will be made to the 16th to 26th steps.

### <2.1.1> 16th Step

After the first to fifth steps are performed, unnecessary portions of the first seed layer 13 and first adhesion layer 12 are removed by etching, as shown in FIG. 14. As this removal method, chemical etching or dry etching can be used. Different removal methods may be employed for the respective layers, or the same removal method may be employed for all layers. For example, the electroless plating layer and the copper layer of the first seed layer 13, and the first adhesion layer 12 can be sequentially removed by chemical etching, but the removal method is not limited to this. The kind of etching solution is appropriately selected depending on the type of metal to be removed.

### <2.1.2> 17th Step

Next, as shown in FIG. 15, a second adhesion layer 15 is first formed in such a manner as to cover the surface of the glass substrate 11, the first adhesion layer 12, the first seed layer 13 and the first conductive layer 14, and then a dielectric layer 16 is formed on the second adhesion layer 15. Thus, the dielectric layer 16 is formed above the glass substrate 11 and the first conductive layer 14. Methods for forming the second adhesion layer 15 and the dielectric layer 16 include a vacuum evaporation method, a sputtering method, an ion plating method, an MBE method, a laser ablation method and a CVD method, but these are not restrictive.

In a case where the adhesion between the first conductive layer 14 and the dielectric layer 16 is sufficient, the second adhesion layer 15 need not be provided. In this case, the dielectric layer 16 is formed in the present step in such a manner as to cover the surface of the glass substrate 11, the first adhesion layer 12, the first seed layer 13, and the first conductive layer 14.

### <2.1.3> 18th Step

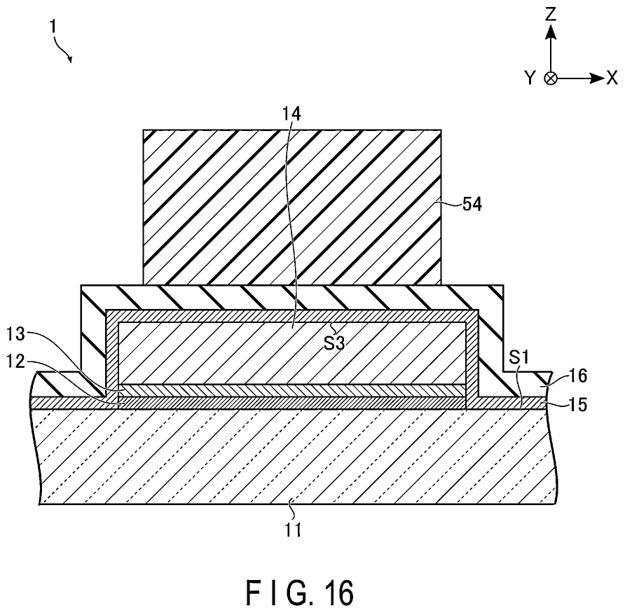

Next, as shown in FIG. 16, a mask pattern is formed on the dielectric layer 16. The mask pattern can be formed using the resist layer 54 in a manner similar to that of the mask pattern described in connection with the first embodiment. The formed mask pattern (resist layer 54) covers part of the dielectric layer 16. The resist layer 54 is formed such that its cross-sectional area (the area of the cross section parallel to the first face S1 of the glass substrate 11) is smaller than the size of the third face S3 of the first conductive layer 14. As the resist layer 54, resist similar to that of the resist layer 51 is used.

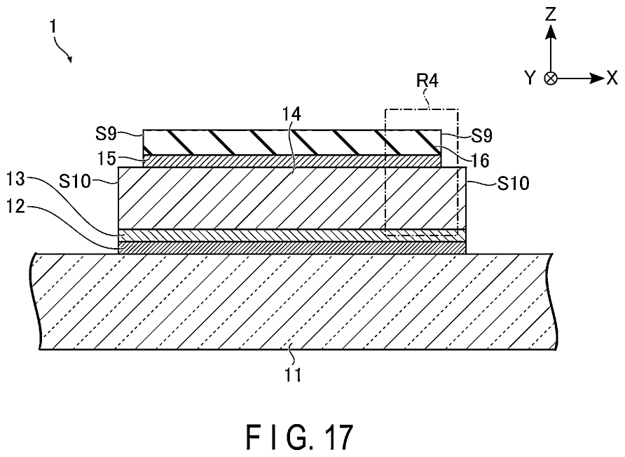

Next, unnecessary portions of the dielectric layer 16 and the second adhesion layer 15 are removed by etching. As this removal method, chemical etching or dry etching can be used. Different removal methods may be employed for the respective layers, or the same removal method may be employed for all layers. Preferably, the dielectric layer 16 is removed by dry etching. Since the resist layer 54 is formed such that the cross-sectional area has the above-mentioned size, the dielectric layer 16 and the second adhesion layer 15 are etched, as shown in FIG. 17. For example, each of the end faces of the dielectric layer 16 and the second adhesion layer 15 is located inward of the end face S10 of the first conductive layer 14. That is, the dielectric layer 16 is formed to have a smaller size than the first conductive layer 14.

### <2.1.4> 19th Step

Next, as shown in FIG. 17, the resist layer 54 is removed to expose the dielectric layer 16. The method for removing the resist layer 54 is similar to the method for removing the resist layer 51.

### <2.1.5> 20th Step

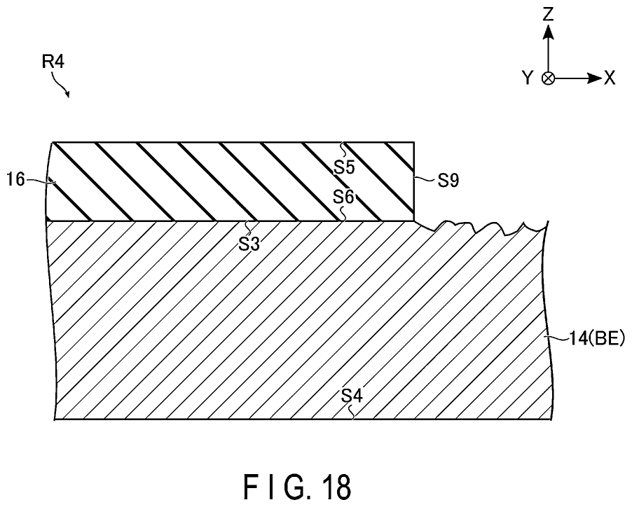

Next, as shown in FIG. 17, the end portion (exposed portion) of the surface of the first conductive layer 14 is etched. Thus, as shown in FIG. 18, roughness is generated at the end portion of the surface of the first conductive layer 14. In the description below, the etching treatment of the present step will be referred to as “seed layer etching pre-treatment” as well. FIG. 18 is a cross-sectional view in which part (region R4) of the cross-sectional view depicted in FIG. 17 is shown in an enlarged scale. It should be noted that in FIG. 18, illustration of the first seed layer 13 and the second adhesion layer 15 is omitted.

In the present step, roughness whose surface roughness is in the range of not less than 30 nm and not more than 70 nm is generated at an end portion of the surface of the first conductive layer 14 by the etching performed. For example, the concentration of the etching solution used for removal of the second seed layer 18 in the 25th step, which will be described later, the process time and the process temperature are determined for the etching such that the surface roughness of the first conductive layer 14 is in the range of not less than 30 nm and not more than 70 nm.

### <2.1.6> 21st Step

Next, as shown in FIG. 19, a third adhesion layer 17 is first formed in such a manner as to cover the surface of the glass substrate 11, the first adhesion layer 12, the first seed layer 13, the first conductive layer 14, the second adhesion layer 15 and the dielectric layer 16, and then a second seed layer 18 is formed on the third adhesion layer 17. Thus, the second seed layer 18 is formed above the glass substrate 11, the first conductive layer 14, and the dielectric layer 16. Examples of the methods for forming the third adhesion layer 17 and the second seed layer 18 include a vacuum evaporation method, a sputtering method, an ion plating method, an MBE method, a laser ablation method, and a CVD method, but these are not restrictive.

In a case where the adhesion between the dielectric layer 16 and the second seed layer 18 is sufficient, the third adhesion layer 17 need not be provided. In this case, the second seed layer 18 is formed in the present step in such a manner as to cover the surface of the glass substrate 11, the first adhesion layer 12, the first seed layer 13, the first conductive layer 14, the second adhesion layer 15 and the dielectric layer 16.

### <2.1.7> 22nd Step

Next, as shown in FIG. 19, a mask pattern is formed on the second seed layer 18. The mask pattern is formed, for example, by providing a resist layer 55 on the second seed layer 18, aligning the resist layer 55 such that the portion where the second conductive layer 19 is to be provided is exposed, and performing pattern exposure and development to the resist layer 55 using a photolithography method. The formed mask pattern (resist layer 55) has an opening at a position corresponding to the second conductive layer 19. The resist layer 55 is formed such that its cross-sectional area (the area of a cross section parallel to the first face S1 of the glass substrate 11) is smaller than the size of the third face S3 of the first conductive layer 14 and is smaller than the size of the fifth face S5 of the dielectric layer 16. As the resist layer 55, resist similar to that of the resist layer 51 is used.

### <2.1.8> 23rd Step

Next, as shown in FIG. 19, by supplying power to the second seed layer 18 and immersing it in a plating solution, a metal layer (electrolytic plating layer) to be used as the second conductive layer 19 is formed on the second seed layer 18 on which the mask pattern (resist layer 55) is not formed (on part of the second seed layer 18). The electrolytic plating is, for example, electrolytic copper plating. The thickness of the second conductive layer 19 formed on the second seed layer 18 can be, for example, in the range of not less than 3 μm and not more than 30 μm.

### <2.1.9> 24th Step

Next, as shown in FIG. 20, the resist layer 55 is removed to expose part of the second seed layer 18. The method for removing the resist layer 55 is similar to the method for removing the resist layer 51.

### <2.1.10> 25th Step

Next, as shown in FIG. 20, a mask pattern is formed on the second seed layer 18 and the second conductive layer 19. The mask pattern can be formed using the resist layer 56 in a similar to that of the mask pattern described above. The formed mask pattern (resist layer 56) covers part of the second seed layer 18 and the second conductive layer 19. The resist layer 56 is formed such that its cross-sectional area (the area of a cross section parallel to the first face S1 of the glass substrate 11) is smaller than the size of the third face S3 of the first conductive layer 14 and is larger than the sizes of the seventh face S7 and the eighth face S8 of the second conductive layer 19. As the resist layer 56, resist similar to that of the resist layer 51 is used.

Next, unnecessary portions of the second seed layer 18 and the third adhesion layer 17 are removed by etching. As this removal method, chemical etching or dry etching can be used. Different removal methods may be employed for the respective layers, or the same removal method may be employed for all layers. For example, the electroless plating layer and the copper layer of the second seed layer 18, and the third adhesion layer 17 can be sequentially removed by chemical etching, but the removal method is not limited to this. The kind of etching solution is appropriately selected depending on the type of metal to be removed. Since the resist layer 56 is formed such that its cross-sectional area has the above-mentioned size, the second seed layer 18 and the third adhesion layer 17 are etched as in the case shown in FIG. 11. For example, each of the end faces of the second seed layer 18 and the third adhesion layer 17 is located inward of the end face S10 of the first conductive layer 14 and is located outward of the end face S11 of the second conductive layer 19.

In the present step, the second seed layer 18 is etched such that the side etching amount A of the first conductive layer 14 is in the range of not less than 1.2 times of the thickness of the second seed layer 18 and not more than 40 times thereof. For example, the second seed layer 18 can be etched in the range of not less than 1.2 times of the thickness of the second seed layer 18 and not more than 40 times thereof.

In the present step, as shown in FIG. 2, the first conductive layer 14 is side-etched to form a side-etched portion SP. Since roughness is generated at the end portion of the surface of the first conductive layer 14 in the 20th step, the etching solution does not uniformly enter the region under the end portion of the dielectric layer 16 during removal of the second seed layer 18 of the present step. As shown in FIG. 3, therefore, the outer circumference OC1 of the contact portion CP of the first conductive layer 14 has a sawtooth shape. Further, the outer circumference OC1 of the contact portion CP of the first conductive layer 14 is located inward of the end face S9 of the dielectric layer 16, for example, in a range of not less than 1.2 times of the thickness of the second seed layer 18 and not more than 40 times thereof.

The removal of unnecessary portions of the second seed layer 18 and the third adhesion layer 17 need not be performed in the present step. For example, prior to the present step, the unnecessary portions of the second seed layer 18 and the third adhesion layer 17 may be removed using the second conductive layer 19 as a mask.

### <2.1.11> 26th Step

Next, by use of a vacuum laminator, a roll coater, or the like, a first insulating layer 21 is formed to cover the surface of the glass substrate 11, the first adhesion layer 12, the first seed layer 13, the first conductive layer 14, the second adhesion layer 15, the dielectric layer 16, the third the adhesion layer 17, the second seed layer 18, and the second conductive layer 19. At this time, the first insulating layer 21 is embedded in a portion (side-etched portion SP) where a portion of the first conductive layer 14 is removed as a result of the removal of the second seed layer 18. Thus, the structure of the wiring substrate 1 shown in FIG. 1 is obtained. As the first insulating layer 21, the above-mentioned material, for example, an insulating resin, is used. The thickness of the first insulating layer 21 can be, for example, greater than 0 μm and not more than 100 μm.

After the present step, the 15th step is performed.

### <2.2> Advantageous Effect

The second embodiment has advantageous effects similar to those of the first embodiment.

### EXAMPLES

Tests conducted in connection with the present invention will be described below.

### Test

In each of Examples 1 to 4, 20 wiring substrates 1 were manufactured using the wiring substrate manufacturing methods according to the first embodiment and the second embodiment. In a case where the wiring substrate manufacturing method according to the first embodiment is adopted, the thickness T of the seed layer refers to the thickness of the first seed layer 13. In a case where the wiring substrate manufacturing method according to the second embodiment is adopted, the thickness T of the seed layer refers to the thickness of the second seed layer 18.

In Example 1, the side etching amount A of the first conductive layer 14 during the etching of the seed layer was set to 0.5 μm. The (side etching amount A)/(thickness T of the seed layer) was set to 2. As a result of the seed layer etching pre-treatment, roughness whose surface roughness is in the range of not less than 30 nm and not more than 70 nm was generated at an end portion of the surface of the first conductive layer 14. By etching the seed layer, an LER in the range of not less than 1000 nm and not more than 5000 nm was formed.

In Example 2, the side etching amount A of the first conductive layer 14 during the etching of the seed layer was set to 1 μm. The (side etching amount A)/(thickness T of the seed layer) was set to 3. As a result of the seed layer etching pre-treatment, roughness whose surface roughness is in the range of not less than 30 nm and not more than 70 nm was generated at an end portion of the surface of the first conductive layer 14. By etching the seed layer, an LER in the range of not less than 1000 nm and not more than 5000 nm was formed.

In Example 3, the side etching amount A of the first conductive layer 14 during the etching of the seed layer was set to 5 μm. The (side etching amount A)/(thickness T of the seed layer) was set to 17. As a result of the seed layer etching pre-treatment, roughness whose surface roughness is in the range of not less than 30 nm and not more than 70 nm was generated at an end portion of the surface of the first conductive layer 14. By etching the seed layer, an LER in the range of not less than 1000 nm and not more than 5000 nm was formed.

In Example 4, the side etching amount A of the first conductive layer 14 during the etching of the seed layer was set to 12 μm. The (side etching amount A)/(thickness T of the seed layer) was set to 40. As a result of the seed layer etching pre-treatment, roughness whose surface roughness is in the range of not less than 30 nm and not more than 70 nm was generated at an end portion of the surface of the first conductive layer 14. By etching the seed layer, an LER in the range of not less than 1000 nm and not more than 5000 nm was formed.

In each of Comparative Example 1 and Comparative Example 2, 20 wiring substrates were manufactured using a manufacturing method similar to that of the first embodiment except that the seed layer etching pre-treatment was not performed.

In Comparative Example 1, the side etching amount A of the first conductive layer 14 during the etching of the seed layer was set to 5 μm. The (side etching amount A)/(thickness T of the seed layer) was set to 17. Roughness whose surface roughness was in the range of not less than 30 nm and not more than 70 nm was not generated at an end portion of the surface of the first conductive layer 14. After the seed layer was etched, an LER in the range of not less than 1000 nm and not more than 5000 nm was not formed.

In Comparative Example 2, the side etching amount A of the first conductive layer 14 during the etching of the seed layer was set to 12 μm. The (side etching amount A)/(thickness T of the seed layer) was set to 40. Roughness whose surface roughness was in the range of not less than 30 nm and not more than 70 nm was not generated at an end portion of the surface of the first conductive layer 14. After the seed layer was etched, an LER in the range of not less than 1000 nm and not more than 5000 nm was not formed.

In Comparative Example 3, 20 wiring substrates were manufactured using a manufacturing method similar to that of the first embodiment, except that the seed layer etching pre-treatment was not performed, the side etching amount A of the first conductive layer 14 during etching the seed layer was set to 0 μm, and the (side etching amount A)/(thickness T of the seed layer) was set to 0. Roughness whose surface roughness was in the range of not less than 30 nm and not more than 70 nm was not generated at an end portion of the surface of the first conductive layer 14. After the seed layer was etched, an LER in the range of not less than 1000 nm and not more than 5000 nm was not formed.

With respect to these wiring substrates, a thermal shock test was conducted. In the thermal shock test, a cycle of varying the ambient temperature of the wiring substrates in the range of −40° C. to +125° C. was repeated 1000 times. After the thermal shock test was conducted, whether or not there was a film residue of the seed layer was confirmed by the observation of cross sections of the wiring substrates. In addition, whether or not peeling occurred between the first conductive layer 14 and dielectric layer 16 of the MIM capacitor C1, and the first insulating layer 21 was confirmed by the observation of cross sections, and a peeling occurrence rate was calculated with respect to 20 specimens. The results are shown in Table 1 below.

### Table 1

TABLE 1

| | | | | | Comparative | Comparative | Comparative |
|---|---|---|---|---|---|---|---|
| | Example 1 | Example 2 | Example 3 | Example 4 | example 1 | example 2 | example 3 |
| Side etching amount A(μm) | 0.5 | 1 | 5 | 12 | 5 | 12 | 0 |
| Side etching amount A/ | 2 | 3 | 17 | 40 | 17 | 40 | 0 |
| Thickness T of seed layer | | | | | | | |
| Surface roughness after seed | Present | Present | Present | Present | Not | Not | Not |
| layer etching pre-treatment | | | | | present | present | present |
| 30 nm~70 nm | | | | | | | |
| LER | Present | Present | Present | Present | Not | Not | Not |
| 1000 nm~5000 nm | | | | | present | present | present |
| Film residue of seed layer | Not | Not | Not | Not | Not | Not | Present |
| | present | present | present | present | present | present | |
| Peeling occurrence rate (%) | 0 | 0 | 0 | 0 | 8 | 14 | — |
| (among 20 specimens) | | | | | | | |

As shown in Table 1, no film residue of the seed layer was observed in the wiring substrates manufactured in Comparative Example 1 and Comparative Example 2. In the wiring substrates manufactured in Comparative Example 3, a film residue of the seed layer was observed. On the other hand, in the wiring substrates manufactured in Example 1 to Example 4, no film residue of the seed layer (first seed layer 13 or second seed layer 18) was observed.

In the wiring substrates manufactured in Comparative Example 1, occurrence of peeling between the first conductive layer 14 and dielectric layer 16 of the MIM capacitor C1, and the first insulating layer 21 was observed (peeling occurrence rate=8%). In the wiring substrates manufactured in Comparative Example 2, occurrence of peeling between the first conductive layer 14 and dielectric layer 16 of the MIM capacitor C1, and the first insulating layer 21 was observed (peeling occurrence rate=14%). On the other hand, in the wiring substrates manufactured in Example 1 to Example 4, no peeling was observed between the first conductive layer 14 and dielectric layer 16 of the MIM capacitor C1, and the first insulating layer 21 (peeling occurrence rate=0%). In addition, the occurrence of peeling at the four corners of the dielectric layer 16 was not observed.

### REFERENCE SIGNS LIST

1 . . . Wiring Substrate, 11 . . . Glass Substrate, 12 . . . First Adhesion Layer, 13 . . . First Seed Layer, 14 . . . First Conductive Layer, 15 . . . Second Adhesion Layer, 16 . . . Dielectric Layer, 17 . . . Third Adhesion Layer, 18 . . . Second Seed Layer, 19 . . . Second Conductive Layer, 21 . . . First Insulating Layer, 22 . . . Third Seed Layer, 23 . . . Third Conductive Layer, 24 . . . Second Insulating Layer

What is claimed is:

1. A wiring substrate comprising:
a glass substrate including a first face;
a capacitor including a first electrode provided above the first face of the glass substrate, a dielectric layer provided above the first electrode, and a second electrode provided above the dielectric layer; and
a first insulating layer covering the first face of the glass substrate and the capacitor,
wherein
a third face of the first electrode that faces a second face of the dielectric layer includes a contact portion that is in contact with the second face of the dielectric layer, and a non-contact portion that is not in contact with the second face of the dielectric layer, and
an outer circumference of the contact portion has a sawtooth shape.

2. The wiring substrate according to claim 1, wherein an LER (Line Edge Roughness) of the contact portion is not less than 1000 nm and not more than 5000 nm.

3. The wiring substrate according to claim 1, wherein an outer circumference of the second face of the dielectric layer has a rectangular shape.

4. The wiring substrate according to claim 1, wherein
the first electrode includes a structure in which a first seed layer and a first conductive layer are stacked, and
the outer circumference of the contact portion is located inward of an end face of the dielectric layer in a range of not less than 1.2 times of a thickness of the first seed layer and not more than 40 times thereof.

5. The wiring substrate according to claim 1, wherein
the second electrode includes a structure in which a second seed layer and a second conductive layer are stacked, and
the outer circumference of the contact portion is located inward of an end face of the dielectric layer in a range of not less than 1.2 times of a thickness of the second seed layer and not more than 40 times thereof.

6. The wiring substrate according to claim 1, wherein a distance between the outer circumference of the contact portion and an end face of the dielectric layer is greater than 0 μm and not more than 12 μm.

7. The wiring substrate according to claim 1, wherein the first electrode is thicker at the contact portion than at the non-contact portion.

8. The wiring substrate according to claim 1, wherein the dielectric layer is made of a transparent material.

9. The wiring substrate according to claim 1, wherein the dielectric layer is made of silicon nitride and has a thickness of not less than 10 nm and not more than 5000 nm.

10. The wiring substrate according to claim 1, wherein the third face of the first electrode is greater in size than the second face of the dielectric layer.

11. The wiring substrate according to claim 1, wherein a fourth face of the dielectric layer facing the second face is greater in size than a fifth face of the second electrode facing the fourth face of the dielectric layer.

12. The wiring substrate according to claim 1, further comprising:
an adhesion layer provided between the first electrode and the dielectric layer.

13. A manufacturing method of a wiring substrate comprising:
forming a first seed layer above a glass substrate;
forming a first conductive layer on part of the first seed layer;
forming a dielectric layer above the first seed layer and the first conductive layer;
forming a second seed layer above the dielectric layer;
forming a second conductive layer on part of the second seed layer;
forming a mask covering the second conductive layer and removing the second seed layer and the dielectric layer;
etching an end portion of a surface of the first conductive layer;
removing the first seed layer; and
forming a first insulating layer to cover a surface of the glass substrate, the first seed layer, the first conductive layer, the dielectric layer, the second seed layer, and the second conductive layer.

14. The manufacturing method according to claim 13, wherein etching the end portion of the surface of the first conductive layer includes generating roughness whose surface roughness is in a range of not less than 30 nm and not more than 70 nm at the end portion of the surface of the first conductive layer.

15. The manufacturing method according to claim 13, wherein removing the first seed layer includes etching the first seed layer in a range of not less than 1.2 times of a thickness of the first seed layer and not more than 40 times thereof.

16. The manufacturing method according to claim 15, wherein forming the first insulating layer includes embedding the first insulating layer in a portion where part of the first conductive layer is removed as a result of removal of the first seed layer.

17. A manufacturing method of a wiring substrate comprising:
forming a first seed layer above a glass substrate;
forming a first conductive layer on part of the first seed layer;
removing the first seed layer;
forming a dielectric layer above the glass substrate and the first conductive layer;
forming a mask covering part of the dielectric layer and removing the dielectric layer;
etching an end portion of a surface of the first conductive layer;
forming a second seed layer above the glass substrate, the first conductive layer, and the dielectric layer;
forming a second conductive layer on part of the second seed layer;
forming a mask covering the second conductive layer and removing the second seed layer; and
forming a first insulating layer to cover a surface of the glass substrate, the first seed layer, the first conductive layer, the dielectric layer, the second seed layer, and the second conductive layer.

18. The manufacturing method according to claim 17, wherein etching the end portion of the surface of the first conductive layer includes generating roughness whose surface roughness is in a range of not less than 30 nm and not more than 70 nm at the end portion of the surface of the first conductive layer.

19. The manufacturing method according to claim 17, wherein removing the second seed layer includes etching the second seed layer in a range of not less than 1.2 times of a thickness of the second seed layer and not more than 40 times thereof.

20. The manufacturing method according to claim 19, wherein forming the first insulating layer includes embedding the first insulating layer in a portion where part of the first conductive layer is removed as a result of removal of the second seed layer.
